(19) United States
(12) Patent Application Publication
(10) Pub. No.: US 2026/0109801 A1
(43) Pub. Date: Apr. 23, 2026

(54) MALEIMIDE RESIN MIXTURE, CURABLE RESIN COMPOSITION, VARNISH, AND CURED PRODUCT THEREOF

(71) Applicant: NIPPON KAYAKU KABUSHIKI KAISHA, Tokyo (JP)

(72) Inventors: Risa HONDA, Tokyo (JP); Takayuki TOHJIMA, Tokyo (JP); Atsuhiko HASEGAWA, Tokyo (JP); Masanori HASHIMOTO, Tokyo (JP); Masataka NAKANISHI, Tokyo (JP)

(73) Assignee: NIPPON KAYAKU KABUSHIKI KAISHA, Tokyo (JP)

(21) Appl. No.: 19/166,958

(22) PCT Filed: Mar. 18, 2024
(86) PCT No.: PCT/JP2024/010521

§ 371 Date: Sep. 19, 2025

(30) Foreign Application Priority Data
Mar. 23, 2023 (JP) 2023-046176
Dec. 25, 2023 (JP) 2023-217507

(51) Int. Cl. C08F 290/12; C08F 8/32; C08F 222/08; C08L 55/00; C08L 71/12; C09D 7/20; C09D 155/00

(52) U.S. Cl. CPC C08F 290/12; C08F 8/32; C08F 222/08; C08L 55/005; C08L 71/126; C09D 7/20; C09D 155/005; C08L 2203/20; C08L 2205/035

(57) ABSTRACT

The present invention provides: a maleimide resin mixture having an excellent low dielectric loss tangent and excellent storage stability in varnished form; a curable resin composition; and a cured product thereof. The maleimide resin mixture comprises: a maleimide resin having repeating units represented by formulas (a) and (b); and bis(3-ethyl-5-methyl-4-maleimidephenyl)methane represented by formula (c), wherein the content of the bismaleimide represented by formula (c) in the total amount of the maleimide resin mixture is 5.0-30.0 area % in terms of GPC area percentage. In the formulas, m is the average number of repetitions and is 0<m<200. n is the average number of repetitions and is 0<n<100. (a) and (b) are each bonded at *, and repetition positions may be random.

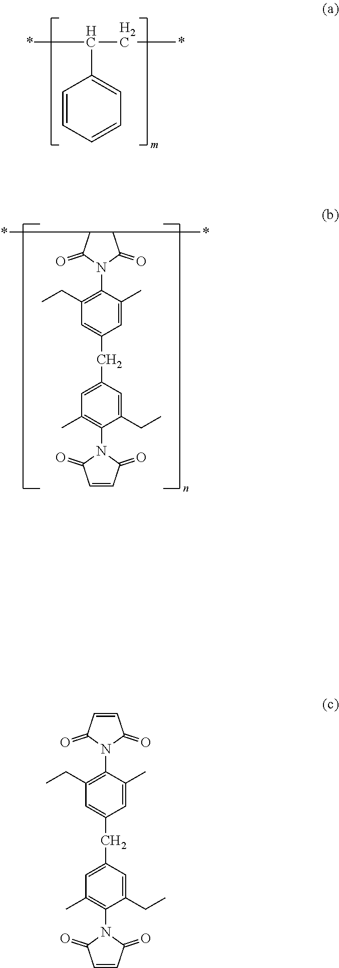

### TECHNICAL FIELD

The present invention relates to a maleimide resin mixture, a curable resin composition, a varnish, and a cured product thereof, which are suitable for use in electric and electronic parts such as semiconductor encapsulants, printed wiring boards, and build-up laminates, lightweight, high-strength materials such as carbon fiber reinforced plastics and glass fiber reinforced plastics, and 3D printing applications.

### BACKGROUND ART

In recent years, the laminates on which electric and electronic components are mounted have come to be used in a wider range of fields, and the required characteristics have become more extensive and sophisticated. Conventional semiconductor chips were mainly mounted on metal lead frames, but semiconductor chips with high processing power, such as central processing units (hereinafter referred to as CPUs), are increasingly being mounted on laminates made of polymer materials.

The fifth generation communication system “5G”, which is currently being developed at an accelerated pace, is expected to further increase capacity and speed. In 5G, the frequency used will become higher, but reducing transmission loss is important to achieve high-speed communication using high frequencies, and even better dielectric properties will be required for board materials. The transmission loss that occurs on a printed circuit board is due to conductor loss and dielectric loss. As described in Non-Patent Document 1, the dielectric loss UD is proportional to the square root of the dielectric constant εᵣ and the dielectric loss tangent tan δ of the dielectric, so it can be said that improving the dielectric loss tangent tan δ, which has a higher contribution rate than the dielectric constant εᵣ, is effective in reducing transmission loss. Thermoplastic materials such as PTFE (polytetrafluoroethylene) and LCP (liquid crystal polymer) are examples of materials with low dielectric loss tangents, but they are poor in moldability compared to thermosetting resins. In light of this, the development of thermosetting resins with excellent dielectric properties is desired. Specifically, the dielectric loss tangent at a frequency of 10 GHz at 25° C. is preferably 0.0016 or less, and more preferably 0.0012 or less. These values are required by the market and correspond to, for example, the values of Panasonic's MEGTORON 8. See Panasonic Holdings Co., Ltd. press release, “Development of “MEGTRON 8”, a low transmission loss multilayer circuit board material for high-speed communication network equipment.”

In addition, in order to meet the demands for smaller size, thinner thickness, and higher density in semiconductor packages (hereinafter referred to as PKG) used in smartphones and the like, thinner PKG substrates are required. As the PKG substrate becomes thinner, its rigidity decreases, and defects such as large warpage occurred due to heating when soldering the PKG to a motherboard (PCB). In order to reduce this, a PKG substrate material with a high Tg (260° C.) above the soldering temperature is required.

In view of this situation, maleimide resins have been studied in recent years as a printed wiring board material in the high frequency region. Maleimide resins themselves are characterized by high heat resistance due to their high crosslink density, but as pointed out in Patent Document 1 below, bismaleimide compounds having an imide structure in the molecule are highly crystalline and have a high melting point of about 150° C., which is close to the 170-180° C. that is the approximate temperature for starting a self-reaction, making them difficult materials to prepare an impregnating varnish, impregnate and dry, or melt-mix with epoxy resins, hardeners, fillers, etc. to produce molding materials.

### CITATION LIST

### Non-Patent Literature

Non-Patent Document 1: “Causes of Signal Loss in High-Speed Signal Transmission on Printed Circuit Boards,” The 29th Japan Institute of Electronics Packaging Spring Conference, Session ID: 16P1-17

### PATENT LITERATURE

Patent document 1: Japanese Patent Application Publication No. 2018-12671

### SUMMARY OF INVENTION

### Problem to be Solved by the Invention

The present invention has been made in view of the above circumstances, and an object of the present invention is to provide a maleimide resin mixture, which has a low dielectric tangent, excellent solvent solubility, and excellent storage stability in a varnish state, as well as a curable resin composition and a cured product thereof.

### Means for Solving the Problem

That is, the present invention relates to the following [1] to [12]. In this application, “(Numerical value 1) to (Numerical value 2)” indicates that the upper and lower limits are included.

[1]

A maleimide resin mixture including:
a maleimide resin having repeating units of the following formulas (a) and (b); and bis(3-ethyl-5-methyl-4-maleimidephenyl)methane represented by the following formula (c),
in which the content of the bis(3-ethyl-5-methyl-4-maleimidephenyl)methane represented by the formula (c) is 5.0 to 30.0 area % in terms of GPC area percentage in the total amount of the maleimide resin mixture.

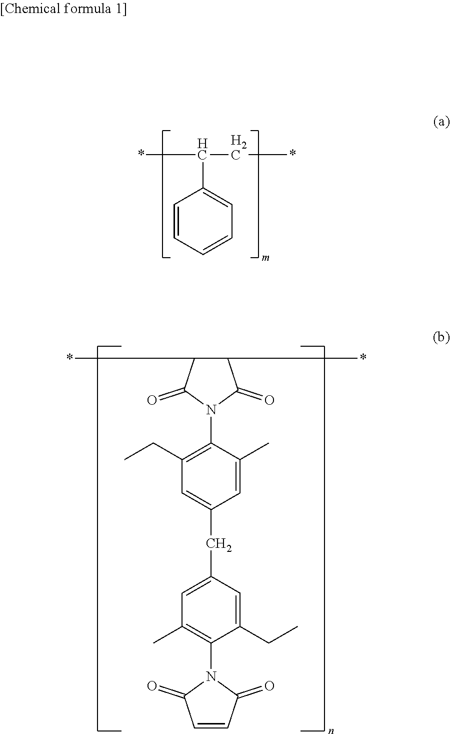

In the above formulas, m is the average number of repeats, and 0<m<200. n is the average number of repeats, and 0<n<100. (a) and (b) are each bonded with *, and the repeat positions may be random.

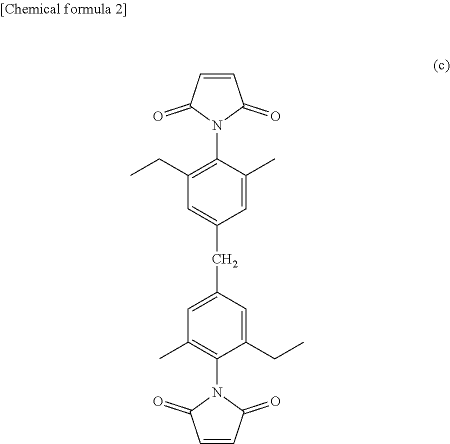 [SMILES: CCc1cc(Cc2cc(C)c(N3C(=O)C=CC3=O)c(CC)c2)cc(C)c1N1C(=O)C=CC1=O]

[2]

The maleimide resin mixture according to the preceding item [1], obtained by reacting a styrene-maleic anhydride copolymer with 4,4′-methylenebis(2-ethyl-6-methylaniline) and maleic anhydride.

[3]

The maleimide resin mixture according to the preceding item [2], in which the weight-average molecular weight of the styrene-maleic anhydride copolymer is 900 or more and less than 10,000.

[4]

A curable resin composition containing the maleimide resin mixture according to any one of the preceding items [1] to [3].

[5]

The curable resin composition according to the preceding item [4], further containing at least one selected from the group consisting of: a maleimide resin other than the maleimide resin mixture, a polyphenylene ether compound, a compound having an ethylenically unsaturated bond, a cyanate ester resin, polybutadiene and modified products thereof, polystyrene and modified products thereof, and polyethylene and modified products thereof.

[6]

The curable resin composition according to the preceding item [4] or [5], further containing a curing accelerator.

[7]

The curable resin composition according to any one of the preceding items [4] to [6], which is for use in a printed wiring board.

[8]

A varnish including the maleimide resin mixture according to any one of the preceding items [1] to [3] and an organic solvent.

[9]

A varnish including the curable resin composition according to any one of the preceding items [4] to [7] and an organic solvent.

[10]

A cured product obtained by curing the maleimide resin mixture according to any one of the preceding items [1] to [3].

[11]

A cured product obtained by curing the curable resin composition according to any one of the preceding items [4] to [7].

[12]

The cured product according to the preceding item [10] or [11], which has a dielectric loss tangent of less than 0.0016 at a frequency of 10 GHz measured at 25° C.

### Effect of the Invention

According to the present invention, it is possible to provide a maleimide resin mixture and a curable resin composition which have a low dielectric tangent, excellent solvent solubility, and excellent storage stability in a varnish state.

### BRIEF DESCRIPTION OF THE DRAWINGS

FIG. 1 A GPC chart of Example 1.

FIG. 2 A GPC chart of Example 2.

FIG. 3 A GPC chart of Example 3.

FIG. 4 A GPC chart of Example 4.

FIG. 5 A GPC chart of Example 5.

FIG. 6 A GPC chart of Example 6.

FIG. 7 A GPC chart of Example 7.

FIG. 8 A GPC chart of Comparative Example 1.

FIG. 9 A GPC chart of Comparative Example 2.

FIG. 10 A GPC chart of Example 8.

### DESCRIPTION OF EMBODIMENTS

Hereinafter, an embodiment of the present invention (hereinafter, also referred to as “the present embodiment”) will be described in further detail.

The maleimide resin mixture of the present embodiment is a maleimide resin mixture including a maleimide resin having repeating units of the following formulas (a) and (b), and bis(3-ethyl-5-methyl-4-maleimidephenyl)methane represented by the following formula (c). Since the maleimide resin of the present embodiment contains asymmetric alkyl substituents at the 2- and 6-positions of the aromatic ring contained in the following formulas (b) and (c), not only can it control the change in dielectric properties due to water absorption, but it can also destroy crystallinity and increase solvent solubility and solvent storage stability.

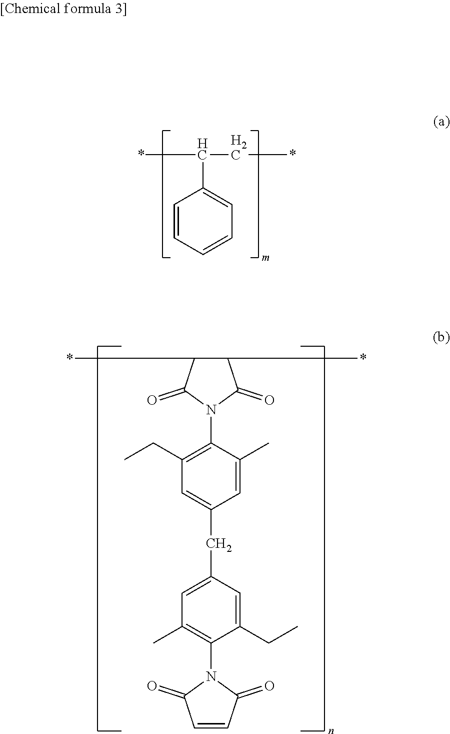

In the above formulas, (a) and (b) are each bonded with *, and the repeating position may be random. m is the average number of repeats, and is preferably 0<m<200, more preferably 1≤m<100, even more preferably 1<m<100, and particularly preferably 5<m<80. n is the average number of repeats, and is more preferably 0<n<100, even more preferably 0<n<90, even more preferably 0<n<80, even more preferably 1≤n<30, and particularly preferably 1.0<n<30. The values of m and n are derived from the styrene-maleic anhydride copolymer used as the raw material. The values of m and n can be determined from the weight average molecular weight of the styrene-maleic anhydride copolymer determined by gel permeation chromatography (GPC), the ratio of styrene to acid anhydride determined from the acid value in the styrene-maleic anhydride copolymer, the molecular weight of the styrene monomer, and the molecular weight of maleic anhydride.

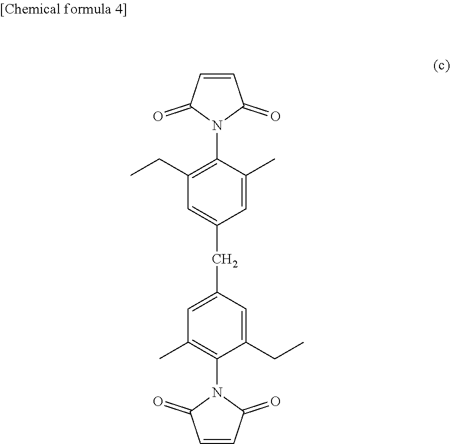 [SMILES: CCc1cc(Cc2cc(C)c(N3C(=O)C=CC3=O)c(CC)c2)cc(C)c1N1C(=O)C=CC1=O]

In the total amount of the maleimide resin mixture of the present embodiment, the content of bis(3-ethyl-5-methyl-4-maleimidephenyl)methane represented by the formula (c) is preferably 5.0 to 30.0 area % in terms of GPC (gel permeation chromatography) area percentage, and more preferably 10.0 to 20.0 area %. If it is more than 30.0%, the proportion of maleimide groups, which are polar groups, increases, resulting in deterioration of dielectric properties, or bis(3-ethyl-5-methyl-4-maleimidephenyl)methane represented by the formula (c) precipitates as crystals, resulting in deterioration of storage stability in a varnish state. If it is less than 5.0%, the proportion of crosslinkable maleimide groups decreases, resulting in deterioration of curability and heat resistance.

An organic solvent can be added to the maleimide resin mixture of the present embodiment to form a varnish. Examples of the organic solvent that can be used include toluene, xylene, acetone, methyl ethyl ketone, methyl isobutyl ketone, dimethylformamide, dimethylacetamide, and N-methylpyrrolidone. The content of the maleimide resin mixture of the present embodiment in the varnish is preferably 30 to 90% by weight, and more preferably 40 to 80% by weight.

The method for producing the maleimide resin mixture of the present embodiment is not particularly limited. The maleimide resin mixture of the present embodiment may be produced by reacting a styrene-maleic anhydride copolymer with 4,4′-methylenebis(2-ethyl-6-methylaniline) and maleic anhydride. Bis(3-ethyl-5-methyl-4-maleimidephenyl)methane represented by formula (c) is produced by reacting 4,4′-methylenebis(2-ethyl-6-methylaniline) and maleic anhydride.

Specifically, the maleimide resin mixture may be produced by a first step in which a styrene-maleic anhydride copolymer is imidized with 4,4′-methylenebis(2-ethyl-6-methylaniline) in a solvent in the presence of a catalyst, and then a second step in which maleic anhydride is added to maleimide the reactant. However, the order of the steps is not limited, and the steps may be reversed or performed simultaneously.

After obtaining the maleimide resin mixture, bis(3-ethyl-5-methyl-4-maleimidephenyl)methane represented by the formula (c) may be additionally mixed.

In the imidization of the first step, gelation due to three-dimensional crosslinking during the reaction step can be prevented by adding an excess of amino groups of 4,4′-methylenebis(2-ethyl-6-methylaniline) per mole of acid anhydride groups contained in the styrene-maleic anhydride copolymer. In this case, the preferred range of the value (α/β) obtained by dividing the number of moles (α) of amino groups of 4,4′-methylenebis(2-ethyl-6-methylaniline) by the number of moles (β) of acid anhydride groups of the styrene-maleic anhydride copolymer is 1.1 to 20, preferably 1.1 to 15, and more preferably 1.1 to 10. If α/β is less than the above range, gelation occurs, making production difficult. Also, if α/β is more than the above range, the amount of polystyrene introduced decreases, and sufficient improvement in electrical properties cannot be expected. Examples of the solvent to be used include, but are not limited to, non-aqueous solvents such as aromatic solvents such as toluene and xylene, aliphatic solvents such as cyclohexane and n-hexane, ethers such as diethyl ether and diisopropyl ether, ester solvents such as ethyl acetate and butyl acetate, and ketone solvents such as methyl isobutyl ketone and cyclopentanone. Two or more of these may be used in combination. In addition to the non-aqueous solvent, aprotic polar solvent may also be used in combination. Examples include dimethyl sulfone, dimethyl sulfoxide, dimethylformamide, dimethylacetamide, 1,3-dimethyl-2-imidazolidinone, and N-methylpyrrolidone, and two or more of these may be used in combination. When using the aprotic polar solvent, it is preferable to use one with a higher boiling point than the non-aqueous solvent to be used in combination. In the reaction, if necessary, hydrochloric acid, phosphoric acid, sulfuric acid, formic acid, p-toluenesulfonic acid, methanesulfonic acid, Lewis acids such as aluminum chloride and zinc chloride, solid acids such as activated clay, acid clay, white carbon, zeolite, and silica-alumina, and acidic ion exchange resins can be used as catalysts. These may be used alone or in combination of two or more. The amount of catalyst used is usually 0.1 to 0.8 moles, preferably 0.2 to 0.7 moles, per mole of amino group of the amine compound used. If the amount of catalyst used is too large, the viscosity of the reaction solution may be too high, making stirring difficult, and if the amount of catalyst used is too small, the reaction may proceed slowly. In the imidization in the second step, an equivalent or more, preferably 1.1 equivalent or more of maleic anhydride is added to the number of moles of amino groups of 4,4′-methylenebis(2-ethyl-6-methylaniline) charged in excess in the first step, to maleimidize all the remaining amino groups, thereby producing the compounds represented by formulas (b) and (c). As the co-catalyst for imidization, a basic co-catalyst such as triethylamine can be used alone or in combination. When a sulfonic acid or the like is used as a catalyst, neutralization with an alkali metal such as sodium hydroxide or potassium hydroxide can be performed before proceeding to the extraction step. In the extraction step, an aromatic hydrocarbon solvent such as toluene or xylene can be used alone, or a non-aromatic hydrocarbon such as cyclohexane or toluene can be used in combination. After extraction, the organic layer is washed with water until the wastewater becomes neutral, and the solvent is distilled off using an evaporator or the like to obtain the target maleimide resin having a polystyrene structure in the molecule.

Styrene-maleic anhydride copolymers are obtained by copolymerizing styrene and maleic anhydride. The polymerization method may be any known method such as radical polymerization, coordination polymerization, or various living polymerizations. For example, the copolymers can be obtained by reacting styrene with maleic anhydride in toluene in the presence of a radical polymerization initiator. In this case, the polymer obtained may be a random polymer or a periodic copolymer, or may be a block polymer or an alternating copolymer. The stereoregularity of the polystyrene segment may be any of syndiotactic, atactic, isotactic, etc.

The weight average molecular weight (Mw) of the styrene-maleic anhydride copolymer, as determined by gel permeation chromatography (GPC), is preferably 100 or more and less than 10,000, more preferably 1,500 or more and less than 9,000, and particularly preferably 2,000 or more and less than 8,000. The number average molecular weight (Mn) is preferably 1,000 or more and less than 5,000, and more preferably 1,000 or more and less than 3,000. When the weight average molecular weight (Mw) and the number average molecular weight (Mn) are less than the upper limit values, gelation can be prevented, and purification by washing with water becomes easy. When the weight average molecular weight (Mw) and the number average molecular weight (Mn) are equal to or more than the lower limit values, the target compound does not volatilize in the solvent distillation step.

The weight average molecular weight (Mw) of the maleimide resin mixture of the present embodiment, as determined by gel permeation chromatography (GPC), is preferably 900 or more and less than 9000, more preferably 1000 or more and less than 7000, and particularly preferably 2000 or more and less than 6000. The number average molecular weight (Mn) is preferably 1000 or more and less than 5000, and more preferably 1000 or more and less than 2000. It is preferable that the weight average molecular weight (Mw) and the number average molecular weight (Mn) are less than the upper limit values, since they have excellent solvent solubility. It is also preferable that they are equal to or more than the lower limit values, since they have less volatile content during molding and are less likely to cause molding defects.

The maleimide equivalent of the maleimide resin mixture of the present embodiment can be determined by potentiometric titration. The maleimide equivalent of the maleimide resin mixture of the present embodiment is preferably 500 g/eq. or more and less than 3000 g/eq., more preferably 500 g/eq. or more and less than 2000 g/eq., and particularly preferably 600 g/eq. or more and less than 1500 g/eq. If the maleimide equivalent is less than the upper limit, the crosslinking component maleimide group is included, which is preferable because the maleimide group is incorporated into the cured network to reduce molding defects and increase the glass transition temperature (Tg). Also, if it is equal to or more than the lower limit, it is preferable because there are few maleimide groups that are highly polar in the cured product, which makes it possible to control changes in properties due to water absorption.

The curable composition of the present embodiment may contain a polymerization inhibitor in addition to the maleimide resin mixture of the present embodiment. By containing a polymerization inhibitor, storage stability is improved and the reaction initiation temperature can be controlled. By controlling the reaction initiation temperature, it becomes easy to ensure fluidity, impregnation into glass cloth and the like is not impaired, and B-stage such as prepreg is easily achieved. If the polymerization reaction proceeds too much during prepreg formation, problems such as difficulty in lamination in the lamination process are likely to occur.

Examples of polymerization inhibitors that can be used include phenol-based, sulfur-based, phosphorus-based, hindered amine-based, nitroso-based, and nitroxyl radical-based polymerization inhibitors. The polymerization inhibitor may be added when synthesizing the maleimide resin mixture of the present embodiment or after synthesis. The polymerization inhibitors can be used alone or in combination of two or more. The amount of the polymerization inhibitor used is usually 0.008 to 1 part by weight, preferably 0.01 to 0.5 parts by weight, relative to 100 parts by weight of the resin component. These polymerization inhibitors can be used alone, but two or more types can be used in combination. In the present embodiment, phenol-based, hindered amine-based, nitroso-based, and nitroxyl radical-based are preferred.

Specific examples of phenol-based polymerization inhibitors include: monophenols such as 2,6-di-t-butyl-p-cresol, butylated hydroxyanisole, 2,6-di-t-butyl-p-ethylphenol, stearyl-β-(3,5-di-t-butyl-4-hydroxyphenyl)propionate, isooctyl-3-(3,5-di-t-butyl-4-hydroxyphenyl)propionate, 2,4-bis-(n-octylthio)-6-(4-hydroxy-3,5-di-t-butylanilino)-1,3,5-triazine, and 2,4-bis[(octylthio)methyl]-o-cresol; bisphenols such as 2,2′-methylenebis(4-methyl-6-t-butylphenol), 2,2′-methylenebis(4-ethyl-6-t-butylphenol), 4,4′-thiobis(3-methyl-6-t-butylphenol), 4,4′-butylidenebis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], N,N′-hexamethylenebis(3,5-di-t-butyl-4-hydroxy-hydrocinnamamide), 2,2-thio-diethylene bis[3-(3,5-di-t-butyl-4-hydroxyphenyl)propionate], 3,5-di-t-butyl-4-hydroxybenzylphosphonate-diethyl ester, 3,9-bis[1,1-dimethyl-2-{β-(3-t-butyl-4-hydroxy-5-methylphenyl)propionyloxy}ethyl]2,4,8,10-tetraoxaspiro[5,5]undecane, bis(3,5-di-t-butyl-4-hydroxybenzylsulfonate ethyl)calcium;
polymeric phenols such as 1,1,3-tris(2-methyl-4-hydroxy-5-t-butylphenyl)butane, 1,3,5-trimethyl-2,4,6-tris(3,5-di-t-butyl-4-hydroxybenzyl)benzene, tetrakis-[methylene-3-(3′,5′-di-t-butyl-4′-hydroxyphenyl)propionate]methane, bis[3,3′-bis-(4′-hydroxy-3′-t-butylphenyl)butyric acid]glycol ester, tris-(3,5-di-t-butyl-4-hydroxybenzyl)-isocyanurate, 1,3,5-tris(3′,5′-di-t-butyl-4′-hydroxybenzyl)-S-triazine-2,4,6-(1H,3H,5H)trione, and tocopherol.

Specific examples of sulfur-based polymerization inhibitors include dilauryl-3,3′-thiodipropionate, dimyristyl-3,3′-thiodipropionate, distearyl-3,3′-thiodipropionate, and the like.

Specific examples of phosphorus-based polymerization inhibitors include: phosphites such as triphenyl phosphite, diphenyl isodecyl phosphite, phenyl diisodecyl phosphite, tris(nonylphenyl)phosphite, diisodecyl pentaerythritol phosphite, tris(2,4-di-t-butylphenyl)phosphite, cyclic neopentane tetrayl bis(octadecyl)phosphite, cyclic neopentane tetrayl bis(2,4-di-t-butylphenyl)phosphite, and cyclic neopentane tetrayl bis(2,4-di-t-butyl-4-methylphenyl)phosphite, and bis[2-t-butyl-6-methyl-4-{2-(octadecyloxycarbonyl)ethyl}phenyl]hydrogenphosphite; and oxaphosphaphenanthrene oxides such as 9,10-dihydro-9-oxa-10-phosphaphenanthrene-10-oxide, 10-(3,5-di-t-butyl-4-hydroxybenzyl)-9,10-dihydro-9-oxa-10-phosphaphenanthrene-10-oxide, and 10-decyloxy-9,10-dihydro-9-oxa-10-phosphaphenanthrene-10-oxide.

Specific examples of hindered amine-based polymerization inhibitors include, but are not limited to: ADK STAB (registered trademark) LA-40MP, ADK STAB LA-40Si, ADK STAB LA-402AF, ADK STAB LA-87, ADK STAB LA-82, ADK STAB LA-81, ADK STAB LA-77Y, ADK STAB LA-77G, ADK STAB LA-72, ADK STAB LA-68, ADK STAB LA-63P, ADK STAB LA-57, and ADK STAB LA-52 (all manufactured by A Co., Ltd.); Chimassorb (registered trademark) 2020FDL, Chimassorb 944FDL, Chimassorb 944LD, Tinuvin (registered trademark) 622SF, Tinuvin PA144, Tnuvin 765, Tinuvin 770DF, Tinuvin XT55FB, Tinuvin 111FDL, Tinuvin 783FDL, and Tinuvin 791FB (all manufactured by BASF Corporation).

Specific examples of the nitroso-based polymerization inhibitor include p-nitrosophenol, N-nitrosodiphenylamine, the ammonium salt of N-nitrosophenylhydroxyamine (cupferron), and the like, with the ammonium salt of N-nitrosophenylhydroxyamine (cupferron) being preferred.

Specific examples of nitroxyl radical polymerization inhibitors include di-tert-butyl nitroxide, 2,2,6,6-tetramethylpiperidine-1-oxyl, 4-hydroxy-2,2,6,6-tetramethylpiperidine-1-oxyl, 4-oxo-2,2,6,6-tetramethylpiperidine-1-oxyl, 4-amino-2,2,6,6-tetramethylpiperidine-1-oxyl, 4-methoxy-2,2,6,6-tetramethylpiperidine-1-oxyl, 4-acetoxy-2,2,6,6-tetramethylpiperidine-1-oxyl, 4-benzoyloxy-2,2,6,6-tetramethylpiperidine-1-oxyl, and the like, but are not limited thereto.

The curable resin composition of the present embodiment may use any known material as a curable resin other than the maleimide resin of the present embodiment and bis(3-ethyl-5-methyl-4-maleimidephenyl)methane. Specifically, examples of the curable resin include maleimide compounds other than the maleimide resin of the present embodiment and bis(3-ethyl-5-methyl-4-maleimidephenyl)methane, phenol resins, epoxy resins, amine resins, compounds containing ethylenic unsaturated bonds, isocyanate resins, polyamide resins, polyimide resins, cyanate ester resins, propenyl resins, methallyl resins, and active ester resins. These may be used alone or in combination. In addition, it is preferable to contain an epoxy resin, a compound containing an ethylenic unsaturated bond, and a cyanate ester resin in view of the balance of heat resistance, adhesion, and dielectric properties. By containing these curable resins, the brittleness of the cured product and adhesion to metals can be improved, and cracks in the package during solder reflow or reliability tests such as thermal cycles can be suppressed.

The amount of the curable resin used is preferably 10 times by weight or less, more preferably 5 times by weight or less, and particularly preferably 3 times by weight or less, relative to the maleimide resin mixture of the present embodiment. The lower limit is preferably 0.5 times by weight or more, and more preferably 1 time by weight or more. If the amount is 10 times by weight or less, the effects of the heat resistance and dielectric properties of the maleimide resin mixture of the present embodiment can be utilized.

As the maleimide compound other than the maleimide resin of the present embodiment and bis(3-ethyl-5-methyl-4-maleimidephenyl)methane, the phenol resin, the epoxy resin, the amine resin, the compound containing an ethylenically unsaturated bond, the isocyanate resin, the polyamide resin, the polyimide resin, the cyanate ester resin, and the active ester resin, the following examples can be used.

Maleimide compounds other than the maleimide resin of the present embodiment and bis(3-ethyl-5-methyl-4-maleimidephenyl)methane: 4,4′-diphenylmethane bismaleimide, polyphenylmethane maleimide, m-phenylene bismaleimide, 2,2′-bis[4-(4-maleimidephenoxy)phenyl]propane, 3,3′-dimethyl-5,5′-diethyl-4,4′-diphenylmethane bismaleimide, 4-methyl-1,3-phenylene bismaleimide, 4,4′-diphenylether bismaleimide, 4,4′-diphenylsulfone bismaleimide, 1,3-bis(3-maleimidephenoxy)benzene, 1,3-bis(4-maleimidephenoxy)benzene), Xylock type maleimide compound (anilix maleimide, manufactured by Mitsui Chemicals Fine Co., Ltd.), biphenylaralkyl-type maleimide compound (solidified by distilling off the solvent under reduced pressure from a resin solution containing the maleimide compound (M2) described in Example 4 of JP 2009-001783 A), bisaminocumylbenzene-type maleimide (maleimide compound described in WO 2020/054601 A), maleimide compounds having an indane structure described in JP 6629692B or WO 2020/217679 A, maleimide compounds described in

MATERIAL STAGE Vol. 18, No. 12, 2019, “Sequel: Epoxy Resin CAS Number Story—Hardener CAS Number Memorandum No. 31 Bismaleimide (1)” and MATERIAL STAGE Vol. 19, No. 2, 2019, “Sequel: Epoxy Resin CAS Number Story—Hardener CAS Number Memorandum No. 32 Bismaleimide (2)”.

### Phenolic Resins:

Polycondensates of phenols (phenol, alkyl-substituted phenols, aromatic-substituted phenols, hydroquinone, resorcin, naphthol, alkyl-substituted naphthol, dihydroxybenzene, alkyl-substituted dihydroxybenzene, dihydroxynaphthalene, etc.) and various aldehydes (formaldehyde, acetaldehyde, alkyl aldehyde, benzaldehyde, alkyl-substituted benzaldehyde, hydroxybenzaldehyde, naphthaldehyde, glutaraldehyde, phthalaldehyde, crotonaldehyde, cinnamaldehyde, furfural, etc.); polycondensates of phenols and various diene compounds (dicyclopentadiene, terpenes, vinylcyclohexene, norbornadiene, vinylnorbornene, tetrahydroindene, divinylbenzene, divinylbiphenyl, diisopropenylbiphenyl, butadiene, isoprene, etc.); polycondensates of phenols and ketones (acetone, methyl ethyl ketone, methyl isobutyl ketone, acetophenone, benzophenone, etc.); phenol resins obtained by polycondensation of phenols and substituted biphenyls (4,4′-bis(chloromethyl)-1,1′-biphenyl and 4,4′-bis(methoxymethyl)-1,1′-biphenyl, etc.) or substituted phenyls (1,4-bis(chloromethyl)benzene, 1,4-bis(methoxymethyl)benzene and 1,4-bis(hydroxymethyl)benzene, etc.); polycondensates of bisphenols and various aldehydes; and polyphenylene ether compounds.

Any known polyphenylene ether compound may be used, but from the viewpoint of heat resistance and electrical properties, a polyphenylene ether compound having an ethylenically unsaturated double bond is preferable, and a polyphenylene ether compound having an acrylic group, a methacrylic group, or a styrene structure is more preferable. Commercially available products include SA-9000-111 (manufactured by SABIC, a polyphenylene ether compound having a methacrylic group), OPE-2St-1200, and OPE-2St-2200 (manufactured by Mitsubishi Gas Chemical Co., Ltd., a polyphenylene ether compound having a styrene structure).

The number average molecular weight (Mn) of the polyphenylene ether compound is preferably 500 to 5000, more preferably 2000 to 5000, and more preferably 2000 to 4000. If the molecular weight is less than 500, the heat resistance of the cured product tends to be insufficient. In addition, if the molecular weight is greater than 5000, the melt viscosity increases and sufficient fluidity cannot be obtained, which tends to lead to molding defects. In addition, the reactivity is also reduced, the curing reaction takes a long time, and the amount of unreacted compounds not incorporated into the curing system increases, which leads to a decrease in the glass transition temperature of the cured product and a decrease in the heat resistance of the cured product.

If the number average molecular weight of the polyphenylene ether compound is 500 to 5000, excellent heat resistance and moldability can be achieved while maintaining excellent dielectric properties. The number average molecular weight here can be specifically measured using gel permeation chromatography or the like.

The polyphenylene ether compound may be one obtained by a polymerization reaction, or one obtained by a redistribution reaction of a high molecular weight polyphenylene ether compound having a number average molecular weight of about 10,000 to 30,000. In addition, these may be used as raw materials and reacted with a compound having an ethylenically unsaturated double bond, such as methacryl chloride, acrylic chloride, or chloromethylstyrene, to impart radical polymerizability. The polyphenylene ether compound obtained by the redistribution reaction is obtained, for example, by heating a high molecular weight polyphenylene ether compound in a solvent such as toluene in the presence of a phenolic compound and a radical initiator to cause a redistribution reaction. The polyphenylene ether compound obtained by the redistribution reaction in this way has hydroxy groups derived from a phenolic compound that contributes to curing at both ends of the molecular chain, and is therefore preferable in that it can maintain even higher heat resistance, and that functional groups can be introduced at both ends of the molecular chain even after modification with a compound having an ethylenically unsaturated double bond. In addition, the polyphenylene ether compound obtained by the polymerization reaction is preferable in that it exhibits excellent fluidity.

The molecular weight of the polyphenylene ether compound can be adjusted by adjusting the polymerization conditions, etc., in the case of a polyphenylene ether compound obtained by a polymerization reaction. In addition, in the case of a polyphenylene ether compound obtained by a redistribution reaction, the molecular weight of the obtained polyphenylene ether compound can be adjusted by adjusting the conditions, etc., of the redistribution reaction. More specifically, it is possible to adjust the amount of the phenolic compound used in the redistribution reaction. That is, the greater the amount of the phenolic compound, the lower the molecular weight of the obtained polyphenylene ether compound. In this case, poly(2,6-dimethyl-1,4-phenylene ether) or the like can be used as the high molecular weight polyphenylene ether compound that undergoes the redistribution reaction. In addition, the phenolic compound used in the redistribution reaction is not particularly limited, but for example, a polyfunctional phenolic compound having two or more phenolic hydroxy groups in the molecule, such as bisphenol A, phenol novolac, cresol novolac, etc., is preferably used. These may be used alone or in combination of two or more.

The content of the polyphenylene ether compound is not particularly limited, but is preferably 10 to 90% by weight, and more preferably 20 to 80% by weight, based on the total weight of the curable resin components. A polyphenylene ether compound content of 10 to 90% by weight is preferable in that a cured product is obtained that is not only excellent in heat resistance, but also fully exhibits the excellent dielectric properties of the polyphenylene ether compound.

Epoxy resins: glycidyl ether-based epoxy resins obtained by glycidylating the above-mentioned phenol resins and alcohols; alicyclic epoxy resins such as 4-vinyl-1-cyclohexene diepoxide and 3,4-epoxycyclohexylmethyl-3,4′-epoxycyclohexanecarboxylate; glycidylamine-based epoxy resins such as tetraglycidyldiaminodiphenylmethane (TGDDM) and triglycidyl-p-aminophenol; and glycidyl ester-based epoxy resins.

Amine resins: diaminodiphenylmethane, diaminodiphenylsulfone, isophoronediamine, naphthalenediamine, aniline novolak, orthoethylaniline novolak; aniline resins obtained by reacting: aniline with xylylene chloride; aniline with substituted biphenyls (4,4′-bis(chloromethyl)-1,1′-biphenyl, 4,4′-bis(methoxymethyl)-1,1′-biphenyl, etc.) or substituted phenyls (1,4-bis(chloromethyl)benzene, 1,4-bis(methoxymethyl)benzene, 1,4-bis(hydroxymethyl)benzene, etc.) described in Japanese Patent No. 6429862.

Compounds containing ethylenically unsaturated bonds: polycondensates of the above-mentioned phenol resins and halogen-based compounds containing ethylenically unsaturated bonds (chloromethylstyrene, allyl chloride, methallyl chloride, acrylic acid chloride, allyl chloride, etc.); polycondensates of phenols containing ethylenically unsaturated bonds (2-allylphenol, 2-propenylphenol, 4-allylphenol, 4-propenylphenol, eugenol, isoeugenol, etc.) and halogen-based compounds (4,4′-bis(methoxymethyl)-1,1′-biphenyl, 1,4-bis(chloromethyl)benzene, 4,4′-difluorobenzophenone, 4,4′-dichlorobenzophenone, 4,4′-dibromobenzophenone, cyanuric chloride, etc.); polycondensates of epoxy resins or alcohols with substituted or unsubstituted acrylates (acrylates, methacrylates, etc.), styrene resins, allyl group-containing compounds, acenaphthyl group-containing compounds (acenaphthylene, etc.), isocyanuric acid derivatives (TAIC manufactured by Mitsubishi Chemical Corporation, MA-DGIC, DA-MGIC, MeDAIC, L-DAIC, DD-1, etc. manufactured by Shikoku Kasei Co., Ltd.), maleimide compounds (phenylmaleimide, 4,4′-diphenylmethane bismaleimide, polyphenylmethane maleimide, m-phenylene bismaleimide, 2,2′-bis[4-(4-maleimide phenoxy]phenyl]propane, 3,3′-dimethyl-5,5′-diethyl-4,4′-diphenylmethane bismaleimide, 4-methyl-1,3-phenylene bismaleimide, 4,4′-diphenyl ether bismaleimide, 4,4′-diphenylsulfone bismaleimide, 1,3-bis (3-maleimide phenoxy) benzene, 1,3-bis (4-maleimide phenoxy) benzene), Zylok type maleimide resin (Anilix Maleimide, manufactured by Mitsui Chemicals Fine Co., Ltd.), biphenyl aralkyl type maleimide resin (solidified by distilling off the solvent under reduced pressure from a resin solution containing the maleimide resin (M2) described in Example 4 of JP 2009-001783 A), bisaminocumylbenzene type maleimide (maleimide resin described in WO 2020/054601).

Isocyanate resins: aromatic diisocyanates such as p-phenylene diisocyanate, m-phenylene diisocyanate, p-xylylene diisocyanate, m-xylylene diisocyanate, 2,4-tolylene diisocyanate, 2,6-tolylene diisocyanate, 4,4′-diphenylmethane diisocyanate, and naphthalene diisocyanate; aliphatic or alicyclic diisocyanates such as isophorone diisocyanate, hexamethylene diisocyanate, 4,4′-dicyclohexylmethane diisocyanate, hydrogenated xylene diisocyanate, norbornene diisocyanate, and lysine diisocyanate; polyisocyanates such as one or more biuret forms of isocyanate monomers or isocyanate forms obtained by trimerizing the above diisocyanate compounds; and polyisocyanates obtained by a urethanization reaction between the above isocyanate compounds and polyol compounds.

Polyamide resin: a polymer made of one or more selected from amino acids (6-aminocaproic acid, 11-aminoundecanoic acid, 12-aminododecanoic acid, p-aminomethylbenzoic acid, etc.) and lactams (ε-caprolactam, ω-undecanelactam, ω-laurolactam) as a main raw material; or a polymer made of one or more diamines and one or more dicarboxylic acids as main raw materials.

Diamines: aliphatic diamines such as ethylenediamine, trimethylenediamine, tetramethylenediamine, pentamethylenediamine, hexamethylenediamine, heptamethylenediamine, octamethylenediamine, nonamethylenediamine, decanediamine, undecanediamine, dodecanediamine, tridecanediamine, tetradecanediamine, pentadecanediamine, hexadecanediamine, heptadecanediamine, octadecanediamine, nonadecanediamine, eicosanediamine, 2-methyl-1,5-diaminopentane, and 2-methyl-1,8-diaminooctane; alicyclic diamines such as cyclohexanediamine, bis-(4-aminocyclohexyl)methane, and bis(3-methyl-4-aminocyclohexyl)methane; aromatic diamines such as xylylenediamine, and the like. Dicarboxylic acids: aliphatic dicarboxylic acids such as oxalic acid, malonic acid, succinic acid, glutaric acid, adipic acid, suberic acid, azelaic acid, sebacic acid, undecanedioic acid, and dodecanedioic acid; aromatic dicarboxylic acids such as terephthalic acid, isophthalic acid, 2-chloroterephthalic acid, 2-methylterephthalic acid, 5-methylisophthalic acid, 5-sodiumsulfoisophthalic acid, hexahydroterephthalic acid, and hexahydroisophthalic acid; alicyclic dicarboxylic acids such as cyclohexanedicarboxylic acid; dialkyl esters and dichlorides of these dicarboxylic acids.

Polyimide resin: a polycondensate of the above diamine and a tetracarboxylic dianhydride.

Tetracarboxylic dianhydride: 4,4′-(hexafluoroisopropylidene)diphthalic anhydride, 5-(2,5-dioxotetrahydro-3-furanyl)-3-methyl-cyclohexene-1,2 dicarboxylic anhydride, pyromellitic dianhydride, 1,2,3,4-benzenetetracarboxylic dianhydride, 3,3′,4,4′-benzophenonetetracarboxylic dianhydride, 2,2′,3,3′-benzophenonetetracarboxylic dianhydride, 3,3′,4,4′-biphenyltetracarboxylic dianhydride, 3,3′,4,4′-diphenyl sulfonetetracarboxylic dianhydride, 2,2′,3,3′-biphenyltetracarboxylic dianhydride, methylene-4,4′-diphthalic dianhydride, 1,1-ethylidene-4,4′-diphthalic dianhydride, 2,2′-propylidene-4,4′-diphthalic dianhydride, 1,2-ethylene-4,4′-diphthalic dianhydride, 1,3-trimethylene-4,4′-diphthalic dianhydride, 1,4-tetramethylene-4,4′-diphthalic dianhydride, 1,5-pentamethylene-4,4′-diphthalic dianhydride, 4,4′-oxydiphthalic dianhydride, thio-4,4′-diphthalic dianhydride, sulfonyl-4,4′-diphthalic dianhydride, 1,3-bis(3,4-dicarboxyphenyl)benzene dianhydride, 1,3-bis(3,4-dicarboxyphenoxy)benzene dianhydride, 1,4-bis(3,4-dicarboxyphenoxy)benzene dianhydride, 1,3-bis[2-(3,4-dicarboxyphenyl)-2-propyl]benzene dianhydride, 1,4-bis[2-(3,4-dicarboxyphenyl)-2-propyl]benzene dianhydride, bis[3-(3,4-dicarboxyphenoxy)phenyl]methane dianhydride, bis[4-(3,4-dicarboxyphenoxy)phenyl]methane dianhydride, 2,2-bis[3-(3,4-dicarboxyphenoxy)phenyl]propane dianhydride, 2,2-bis[4-(3,4-dicarboxyphenoxy)phenyl]propane dianhydride, bis(3,4-dicarboxyphenoxy)dimethylsilane dianhydride, 1,3-bis(3,4-dicarboxyphenyl)-1,1,3,3-tetramethyldisiloxane dianhydride, 2,3,6,7-naphthalene tetracarboxylic dianhydride, 1,4,5,8-naphthalene tetracarboxylic dianhydride, 1,2,5,6-naphthalene tetracarboxylic dianhydride, 3,4,9,10-perylene tetracarboxylic dianhydride, 2,3,6,7-anthracene tetracarboxylic dianhydride, 1,2,7,8-phenanthrene tetracarboxylic dianhydride, ethylene tetracarboxylic dianhydride, 1,2,3,4-butane tetracarboxylic dianhydride, 1,2,3,4-cyclobutane tetracarboxylic dianhydride, cyclopentane tetracarboxylic dianhydride, carboxylic dianhydride, cyclohexane-1,2,3,4-tetracarboxylic dianhydride, cyclohexane-1,2,4,5-tetracarboxylic dianhydride, 3,3′,4,4′-bicyclohexyltetracarboxylic dianhydride, carbonyl-4,4′-bis(cyclohexane-1,2-dicarboxylic acid) dianhydride, methylene-4,4′-bis(cyclohexane-1,2-dicarboxylic acid) dianhydride, 1,2-ethylene-4,4′-bis(cyclohexane-1,2-dicarboxylic acid) dianhydride, 1,1-ethylidene-4,4′-bis(cyclohexane-1,2-dicarboxylic acid) dianhydride, 2,2-propylidene-4,4′-bis(cyclohexane-1,2-dicarboxylic acid) dianhydride, oxy-4,4′-bis(cyclohexane-1,2-dicarboxylic acid) dianhydride, thio-4,4′-bis(cyclohexane-1,2-dicarboxylic acid)dianhydride, sulfonyl-4,4′-bis(cyclohexane-1,2-dicarboxylic acid)dianhydride, bicyclo[2,2,2]oct-7-ene-2,3,5,6-tetracarboxylic acid dianhydride, rel-[1S,5R,6R]-3-oxabicyclo[3,2,1]octane-2,4-dione-6-spiro-3′-(tetrahydrofuran-2′,5′-dione), 4-(2,5-dioxotetrahydrofuran-3-yl)-1,2,3,4-tetrahydronaphthalene-1,2-dicarboxylic acid anhydride, ethylene glycol-bis-(3,4-dicarboxylic acid anhydride phenyl)ether, 4,4′-biphenyl bis(trimellitic acid monoester acid anhydride), 9,9′-bis(3,4-dicarboxyphenyl)fluorene dianhydride.

Cyanate ester resin: a cyanate ester compound obtained by reacting a phenol resin with a cyanogen halide. Specific examples include dicyanatobenzene, tricyanatobenzene, dicyanatonaphthalene, dicyanatobiphenyl, 2,2′-bis(4-cyanatophenyl)propane (BisA-OCN, manufactured by Mitsubishi Gas Chemical Co., Inc.), bis(4-cyanatophenyl)methane, bis(3,5-dimethyl-4-cyanatophenyl)methane, 2,2′-bis(3,5-dimethyl-4-cyanatophenyl)propane, 2,2′-bis(4-cyanatophenyl)ethane, 2,2′-bis(4-cyanatophenyl)hexafluoropropane, bis(4-cyanatophenyl)sulfone, bis(4-cyanatophenyl)thioether, phenol novolac cyanate, and phenol-dicyclopentadiene co-condensates in which the hydroxy groups have been converted to cyanate groups, but are not limited thereto.

In addition, the cyanate ester compound, the synthesis method of which is described in Japanese Patent Application Laid-Open No. 2005-264154, is particularly preferred as the cyanate ester compound because it has low moisture absorption, excellent flame retardancy, and excellent dielectric properties.

The cyanate ester resin may contain a catalyst such as zinc naphthenate, cobalt naphthenate, copper naphthenate, lead naphthenate, zinc octylate, tin octylate, lead acetylacetonate, dibutyltin maleate, or commercially available 18% Octope Zn (manufactured by Hope Pharmaceutical Co., Ltd.) in order to trimerize the cyanate group to form a sym-triazine ring, if necessary. The catalyst is usually used in an amount of 0.0001 to 0.10 parts by weight, preferably 0.00015 to 0.0015 parts by weight, per 100 parts by weight of the total weight of the curable resin composition.

Active ester resin: A compound having one or more active ester groups in one molecule can be used as a curing agent for a curable resin other than the maleimide resin mixture of the present embodiment, such as an epoxy resin, if necessary. As the active ester resin, a highly reactive compound having two or more ester groups in one molecule, such as phenol esters, thiophenol esters, N-hydroxyamine esters, and esters of heterocyclic hydroxy compounds, is preferred. The active ester resin is preferably one obtained by a condensation reaction between at least one compound of a carboxylic acid compound and a thiocarboxylic acid compound and at least one compound of a hydroxy compound and a thiol compound. In particular, from the viewpoint of improving heat resistance, an active ester resin obtained from a carboxylic acid compound and a hydroxy compound is preferred, and an active ester resin obtained from a carboxylic acid compound and at least one compound of a phenol compound and a naphthol compound is preferred.

Examples of the carboxylic acid compound include benzoic acid, acetic acid, succinic acid, maleic acid, itaconic acid, phthalic acid, isophthalic acid, terephthalic acid, and pyromellitic acid.

Examples of phenol compounds or naphthol compounds include hydroquinone, resorcin, bisphenol A, bisphenol F, bisphenol S, phenolphthaline, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, dicyclopentadiene-type diphenol compounds, phenol novolak, etc. Here, the term “dicyclopentadiene-type diphenol compound” refers to a diphenol compound obtained by condensing one molecule of dicyclopentadiene with two molecules of phenol.

Specific preferred examples of the active ester resin include active ester resins containing a dicyclopentadiene-type diphenol structure, active ester resins containing a naphthalene structure, active ester resins containing an acetylated product of phenol novolac, and active ester resins containing a benzoylated product of phenol novolac. Among these, active ester resins containing a naphthalene structure and active ester resins containing a dicyclopentadiene-type diphenol structure are more preferred. The “dicyclopentadiene-type diphenol structure” refers to a divalent structural unit consisting of phenylene-dicyclopentylene-phenylene.

Commercially available active ester resins include, for example: active ester resins containing a dicyclopentadiene-type diphenol structure such as “EXB9451”, “EXB9460”, “EXB9460S”, “HPC-8000-65T”, “HPC-8000H-65TM”, “EXB-8000L-65TM”, and “EXB-8150-65T” (manufactured by DIC Corporation); active ester resins containing a bisphenol A structure such as “Unifiner Series” (manufactured by Unitika Ltd.); active ester resins containing a naphthalene structure such as “EXB9416-70BK” (manufactured by DIC Corporation); active ester resins containing an acetylated phenol novolac such as “DC808” (manufactured by Mitsubishi Chemical Corporation); active ester resins containing a benzoylated phenol novolac such as “YLH1026”, “YLH1030”, and “YLH1048” (manufactured by Mitsubishi Chemical Corporation); an active ester resin which is an acetylated phenol novolac such as “DC808” (manufactured by Mitsubishi Chemical Corporation); and an active ester resin containing a phosphorus atom such as “EXB-9050L-62M” (manufactured by DIC Corporation).

The curable resin composition of the present embodiment can also be improved in curability by using a curing accelerator (curing catalyst) in combination. As a specific example of a curing accelerator that can be used, it is preferable to use aradical polymerization initiator for the purpose of promoting self-polymerization of a radically polymerizable curable resin such as an olefin compound or a maleimide resin, or radical polymerization with other components. Examples of the radical polymerization initiator that can be used are known curing accelerators including, but are not particularly limited to: ketone peroxides such as methyl ethyl ketone peroxide and acetylacetone peroxide; diacyl peroxides such as benzoyl peroxide; dialkyl peroxides such as dicumyl peroxide and 1,3-bis-(t-butylperoxyisopropyl)-benzene; peroxyketals such as t-butylperoxybenzoate and 1,1-di-t-butylperoxycyclohexane; alkylperesters such as α-cumylperoxyneodecanoate, t-butylperoxyneodecanoate, t-butylperoxypivalate, 1,1,3,3-tetramethylbutylperoxy-2-ethylhexanoate, t-amylperoxy-2-ethylhexanoate, t-butylperoxy-2-ethylhexanoate, t-amylperoxy-3,5,5-trimethylhexanoate, t-butylperoxy-3,5,5-trimethylhexanoate, and t-amylperoxybenzoate; peroxycarbonates such as di-2-ethylhexyl peroxydicarbonate, bis(4-t-butylcyclohexyl)peroxydicarbonate, t-butylperoxyisopropyl carbonate, 1,6-bis(t-butylperoxycarbonyloxy)hexane; organic peroxides such as t-butyl hydroperoxide, cumene hydroperoxide, t-butyl peroxyoctoate, lauroyl peroxide; and azo compounds such as azobisisobutyronitrile, 4,4′-azobis(4-cyanovaleric acid), and 2,2′-azobis(2,4-dimethylvaleronitrile). Ketone peroxides, diacyl peroxides, hydroperoxides, dialkyl peroxides, peroxyketals, alkyl peresters, peroxycarbonates, etc. are preferred, with dialkyl peroxides being more preferred. The amount of radical polymerization initiator added is preferably 0.01 to 5 parts by weight, particularly preferably 0.01 to 3 parts by weight, per 100 parts by weight of the curable resin composition. If the amount of radical polymerization initiator used is too large, the molecular weight does not extend sufficiently during the polymerization reaction.

In addition, a curing accelerator other than the radical polymerization initiator may be added or used in combination as necessary. Specific examples of the curing accelerator that can be used include: imidazoles such as 2-methylimidazole, 2-ethylimidazole, and 2-ethyl-4-methylimidazole; tertiary amines such as 2-(dimethylaminomethyl)phenol and 1,8-diaza-bicyclo(5,4,0)undecene-7; phosphines such as triphenylphosphine; quaternary ammonium salts such as tetrabutylammonium salt, triisopropylmethylammonium salt, trimethyldecanylammonium salt, cetyltrimethylammonium salt, and hexadecyltrimethylammonium hydroxide; quaternary phosphonium salts such as triphenylbenzylphosphonium salt, triphenylethylphosphonium salt, and tetrabutylphosphonium salt (the counter ion of the quaternary salt may be a halogen, an organic acid ion, a hydroxide ion, or the like, and is not particularly specified, but an organic acid ion or hydroxide ion is particularly preferred); tin octylate; transition metal compounds (transition metal salts) such as zinc compounds such as zinc carboxylate (zinc 2-ethylhexanoate, zinc stearate, zinc behenate, zinc myristylate) and zinc phosphate ester (zinc octylphosphate, zinc stearylphosphate, etc.). The curing accelerator is used in an amount of 0.01 to 5.0 parts by weight per 100 parts by weight of the epoxy resin, as required.

The curable resin composition of the present embodiment may contain a phosphorus-containing compound as a flame retardant-imparting component. The phosphorus-containing compound may be a reactive type or an additive type. Specific examples of the phosphorus-containing compound include: phosphate esters such as trimethyl phosphate, triethyl phosphate, tricresyl phosphate, trixylyleneyl phosphate, cresyl diphenyl phosphate, cresyl-2,6-dixylyleneyl phosphate, 1,3-phenylene bis(dixylyl phosphate), 1,4-phenylene bis(dixylyl phosphate), and 4,4′-biphenyl(dixylyl phosphate); phosphanes such as 9,10-dihydro-9-oxa-10-phosphaphenanthrene-10-oxide, 10-(2,5-dihydroxyphenyl)-10H-9-oxa-10-phosphaphenanthrene-10-oxide; phosphorus-containing epoxy compounds obtained by reacting an epoxy resin with active hydrogen of the phosphanes; and red phosphorus. Among them, phosphate esters, phosphanes, or phosphorus-containing epoxy compounds are preferred, and 1,3-phenylenebis(dixylyl phosphate), 1,4-phenylenebis(dixylyl phosphate), 4,4′-biphenyl(dixylyl phosphate), or phosphorus-containing epoxy compounds are particularly preferred. The content ratio of the phosphorus-containing compound (phosphorus-containing compound)/(total epoxy resin) is preferably in the range of 0.1 to 0.6 (weight ratio). If it is 0.1 or less, the flame retardancy is insufficient, and if it is 0.6 or more, there is a concern that it may adversely affect the moisture absorption and dielectric properties of the cured product.

Furthermore, a light stabilizer may be added to the curable resin composition of the present embodiment as necessary. As the light stabilizer, a hindered amine light stabilizer (HALS) or the like is preferable. Although there is no particular limitation on the HALS, representative ones include: a polycondensate of dibutylamine/1,3,5-triazine/N,N′-bis(2,2,6,6-tetramethyl-4-piperidyl-1,6-hexamethylenediamine) and N-(2,2,6,6-tetramethyl-4-piperidyl)butylamine; a polycondensate of dimethyl succinate-1-(2-hydroxyethyl)-4-hydroxy-2,2,6,6-tetramethylpiperidine; poly[{6-(1,1,3,3-tetramethylbutyl)amino-1,3,5-triazine-2,4-diyl}{(2,2,6,6-tetramethyl-4-piperidyl)imino}hexamethylene{(2,2,6,6-tetramethyl-4-piperidyl)imino}], bis(1,2,2,6,6-pentamethyl-4-piperidyl)[[3,5-bis(1,1-dimethylethyl)-4-hydroxyphenyl]methyl]butyl malonate, bis(2,2,6,6-tetramethyl-4-piperidyl)sebacate, bis(1,2,2,6,6-pentamethyl-4-piperidyl)sebacate, bis(1-octyloxy-2,2,6,6-tetramethyl-4-piperidyl)sebacate, 2-(3,5-di-t-butyl-4-hydroxybenzyl)-2-n-butylmalonate bis(1,2,2,6,6-pentamethyl-4-piperidyl), etc. Only one type of HALS may be used, or two or more types may be used in combination.

Furthermore, the curable resin composition of the present embodiment may contain a binder resin as required. Examples of binder resins include, but are not limited to, butyral resins, acetal resins, acrylic resins, epoxy-nylon resins, NBR-phenol resins, epoxy-NBR resins, polyamide resins, polyimide resins, and silicone resins. The amount of binder resin to be added is preferably within a range that does not impair the flame retardancy and heat resistance of the cured product, and is preferably 0.05 to 50 parts by weight, more preferably 0.05 to 20 parts by weight, based on 100 parts by weight of the resin component, as required.

Furthermore, inorganic fillers may be added to the curable resin composition of the present embodiment as necessary. The inorganic fillers may be powders such as fused silica, crystalline silica, porous silica, alumina, zircon, calcium silicate, calcium carbonate, quartz powder, silicon carbide, silicon nitride, boron nitride, zirconia, aluminum nitride, graphite, forsterite, steatite, spinel, mullite, titania, talc, clay, iron oxide, asbestos, glass powder, etc., or may be obtained by making these into a spherical or crushed shape. In particular, when a curable resin composition for semiconductor encapsulation is obtained, the amount of the inorganic filler used is usually 80 to 92% by weight, preferably 83 to 90% by weight, in the curable resin composition.

The curable resin composition of the present embodiment may contain known additives as necessary. Specific examples of additives that can be used include: polybutadiene and modified products thereof, modified products of acrylonitrile copolymers, polyphenylene ether, polystyrene, polyethylene, polyimide, fluororesin, silicone gel, silicone oil, surface treatment agents for fillers such as silane coupling agents, mold release agents, and colorants such as carbon black, phthalocyanine blue, and phthalocyanine green. The amount of these additives to be added is preferably 30 parts by mass or less, more preferably 20 parts by mass or less, and particularly preferably 10 parts by mass or less, relative to 100 parts by mass of the curable resin composition. From the viewpoints of low water absorption and electrical properties, polybutadiene and modified products thereof, polyphenylene ether, polystyrene, polyethylene, fluororesin, etc. are preferred. From the viewpoints of electrical properties, adhesion, and low water absorption, polybutadiene and modified products thereof are preferred. Specific examples include: butadiene-based thermoplastic elastomers such as styrene-butadiene copolymers (SBR: RICON-100, RICON-181, RICON-184, all manufactured by Cray Valley Corporation, etc.) and acrylonitrile-butadiene copolymers; and styrene-based thermoplastic elastomers such as styrene-butadiene-styrene copolymers (SBS), hydrogenated styrene-butadiene-styrene copolymers, styrene-isoprene-styrene copolymers (SIS), hydrogenated styrene-isoprene-styrene copolymers, and hydrogenated styrene (butadiene/isoprene)-styrene copolymers. These styrene-based thermoplastic elastomers may be used alone or in combination of two or more kinds. Among these high molecular weight materials, styrene-based thermoplastic elastomers such as styrene-butadiene-styrene copolymer, hydrogenated styrene-butadiene-styrene copolymer, styrene-isoprene-styrene copolymer, hydrogenated styrene-isoprene-styrene copolymer, and hydrogenated styrene (butadiene/isoprene)-styrene copolymer are preferred, and in particular, styrene-isoprene-styrene copolymer, hydrogenated styrene-butadiene-styrene copolymer, hydrogenated styrene-isoprene-styrene copolymer, and hydrogenated styrene (butadiene/isoprene)-styrene copolymer are more preferred because they have higher heat resistance and are less susceptible to oxidative degradation. Specific examples are Septon (registered trademark) 1020, Septon 2002, Septon 2004F, Septon 2005, Septon 2006, Septon 2063, Septon 2104, Septon 4003, Septon 4044, Septon 4055, Septon 4077, Septon 4099, Septon 8004, Septon 8006, Septon 8007L, Septon HG252, Septon V9827, Hybrar (registered trademark) 7125 (hydrogenated), Hybrar 7215F, Hybrar-7311F (all manufactured by Kuraray Co., Ltd.). The weight average molecular weight of the styrene-based thermoplastic elastomer is not particularly limited as long as it is 10,000 or more, but if it is too large, compatibility with polyphenylene ether compounds, low molecular weight components with a weight average molecular weight of about 50 to 1,000, and oligomer components with a weight average molecular weight of about 1,000 to 5,000 deteriorates, making it difficult to ensure mixing and solvent stability, so it is preferably about 10,000 to 300,000. In general, in the case of compounds containing heteroatoms such as oxygen and nitrogen, such as bismaleimide and polymaleimide, it is difficult to ensure compatibility with low-polarity compounds such as compounds mainly composed of hydrocarbons or compounds composed only of hydrocarbons, among the above additives and the above curable resin components, due to their polarity. On the other hand, the maleimide resin mixture of the present embodiment is not designed to actively introduce heteroatoms such as oxygen and nitrogen (having few polar groups), and therefore has excellent compatibility with materials having low polarity and low dielectric tangent and compounds composed only of hydrocarbons.

The curable resin composition of the present embodiment can be obtained by uniformly mixing the above components in a predetermined ratio, and then pre-curing the composition at 130 to 180° C. for 30 to 500 seconds, and then post-curing the composition for 2 to 15 hours at 150 to 250° C. to allow the curing reaction to proceed sufficiently, thereby obtaining the cured product of the present embodiment. Alternatively, the components of the curable resin composition can be uniformly dispersed or dissolved in a solvent or the like, and the resin composition can be cured after removing the solvent.

The curable resin composition of the present embodiment thus obtained has moisture resistance, heat resistance, and high adhesion. Therefore, the curable resin composition of the present embodiment can be used in a wide range of fields requiring moisture resistance, heat resistance, and high adhesion. Specifically, it is useful as an insulating material, a laminate (printed wiring board, BGA substrate, build-up substrate, etc.), a sealing material, a resist, and other materials for all electrical and electronic components. It can also be used in fields such as coating materials, adhesives, and 3D printing, in addition to molding materials and composite materials. In particular, solder reflow resistance is beneficial in semiconductor sealing.

The semiconductor device is sealed with the curable resin composition of the present embodiment. Examples of the semiconductor device include a dual in-line package (DIP), a quad flat package (QFP), a ball grid array (BGA), a chip size package (CSP), a small outline package (SOP), a thin small outline package (TSOP), and a thin quad flat package (TQFP).

The method for preparing the curable resin composition of the present embodiment is not particularly limited, but each component may be mixed uniformly or may be prepolymerized. For example, the maleimide resin mixture of the present embodiment is prepolymerized by heating in the presence or absence of a catalyst and in the presence or absence of a solvent. Similarly, in addition to the maleimide resin mixture of the present embodiment, epoxy resins, amine compounds, other maleimide compounds, cyanate ester compounds, phenolic resins, and curing agents such as acid anhydride compounds and other additives may be added to prepolymerize. The mixing of each component or prepolymerization is carried out using, for example, an extruder, kneader, rolls, etc. in the absence of a solvent, or a reaction kettle with a stirrer, etc. in the presence of a solvent.

As a method of uniform mixing, the materials are mixed at a temperature in the range of 50 to 100° C. by kneading with a device such as a kneader, roll, or planetary mixer to obtain a uniform resin composition. The obtained resin composition is crushed and then molded into a cylindrical tablet shape using a molding machine such as a tablet machine, or into a granular powder or powder molded body, or these compositions can be melted on a surface support and molded into a sheet shape with a thickness of 0.05 mm to 10 mm to obtain a molded curable resin composition. The obtained molded body is a non-sticky molded body at 0 to 20° C., and even if stored at −25 to 0° C. for one week or more, the flowability and curability are hardly reduced.

The obtained molded body can be molded into a cured product using a transfer molding machine or a compression molding machine.

An organic solvent may be added to the curable resin composition of the present embodiment to form a varnish-like composition (hereinafter, simply referred to as varnish). The curable resin composition of the present embodiment may be dissolved in a solvent such as toluene, xylene, acetone, methyl ethyl ketone, methyl isobutyl ketone, dimethylformamide, dimethylacetamide, or N-methylpyrrolidone as necessary to form a varnish, which may then be impregnated into a substrate such as glass fiber, carbon fiber, polyester fiber, polyamide fiber, alumina fiber, or paper, and dried by heating to obtain a prepreg. The prepreg may then be heat-press molded to form a cured product of the curable resin composition of the present embodiment. The solvent used in this case is usually 10 to 70% by weight, preferably 15 to 70% by weight, of the mixture of the curable resin composition of the present embodiment and the solvent. In the case of a liquid composition, a cured product of a curable resin containing carbon fiber may be obtained as it is, for example, by the RTM (Resin Transfer Molding) method.

The curable composition of the present embodiment can also be used as a modifier for a film-type composition. Specifically, it can be used to improve flexibility and the like in the B-stage. Such a film-type resin composition is obtained as a sheet-like adhesive by applying the curable resin composition varnish of the present embodiment onto a release film, removing the solvent under heating, and then performing B-stage formation. This sheet-like adhesive can be used as an interlayer insulating layer in a multilayer substrate or the like.

The curable resin composition of the present embodiment can be heated and melted to reduce the viscosity, and impregnated into reinforcing fibers such as glass fibers, carbon fibers, polyester fibers, polyamide fibers, and alumina fibers to obtain a prepreg. Specific examples thereof include: glass fibers such as E glass cloth, D glass cloth, S glass cloth, Q glass cloth, spherical glass cloth, NE glass cloth, and T glass cloth; inorganic fibers other than glass; and organic fibers such as polyparaphenylene terephthalamide (Kevlar (registered trademark), manufactured by DuPont Co., Ltd.), wholly aromatic polyamide, polyester, polyparaphenylene benzoxazole, polyimide, and carbon fibers, but are not particularly limited thereto. The shape of the substrate is not particularly limited, but examples thereof include woven fabric, nonwoven fabric, roving, chopped strand mat, and the like. In addition, as the weaving method of the woven fabric, plain weave, saddle weave, twill weave, and the like are known, and these known weaves can be appropriately selected and used depending on the intended use and performance. In addition, woven fabrics that have been subjected to fiber opening treatment and glass woven fabrics that have been surface-treated with a silane coupling agent or the like are preferably used. The thickness of the substrate is not particularly limited, but is preferably about 0.01 to 0.4 mm. A prepreg can also be obtained by impregnating reinforcing fibers with the varnish and drying the fibers by heating.

The laminate of the present embodiment includes one or more of the prepregs. The laminate is not particularly limited as long as it includes one or more prepregs, and may have any other layer. The method for producing the laminate can be appropriately applied by a generally known method, and is not particularly limited. For example, when forming the metal foil-clad laminate, a multi-stage press machine, a multi-stage vacuum press machine, a continuous molding machine, an autoclave molding machine, etc. can be used, and the prepregs are laminated together and heated and pressurized to obtain a laminate. At this time, the heating temperature is not particularly limited, but is preferably 65 to 300° C., and more preferably 120 to 270° C. The pressure to be applied is not particularly limited, but if the pressure is too high, it is difficult to adjust the solid content of the resin of the laminate, and the quality is not stable, and if the pressure is too low, air bubbles and adhesion between the laminates are deteriorated, so that 2.0 to 5.0 MPa is preferable, and 2.5 to 4.0 MPa is more preferable. The laminate of the present embodiment includes a layer made of metal foil, and can be suitably used as a metal foil-clad laminate described later.

The prepreg is cut into a desired shape and laminated with copper foil or the like as necessary. The laminate is then heated and cured while applying pressure thereto by press molding, autoclave molding, sheet winding molding or the like, to obtain an electrical and electronic laminate (printed wiring board) or a carbon fiber reinforced material.

The cured product of the present embodiment can be used in various applications such as molding materials, adhesives, composite materials, paints, etc. The cured product of the curable resin composition described in the present embodiment exhibits excellent heat resistance and dielectric properties, and is therefore suitable for use in electric and electronic parts such as encapsulants for semiconductor elements, encapsulants for liquid crystal display elements, encapsulants for organic EL elements, printed wiring boards, and build-up laminates, as well as composite materials for lightweight, high-strength structural materials such as carbon fiber reinforced plastics and glass fiber reinforced plastics.

The cured product of the present embodiment preferably has a dielectric tangent, measured at 25° C. and a frequency of 10 GHz, of less than 0.0016, and more preferably less than 0.0013.

### EXAMPLES

The present invention will now be described in more detail with reference to examples. Unless otherwise specified, all parts are by weight. However, the present invention is not limited to these examples.

The various analytical methods used in the examples are described below.

### <Gel Permeation Chromatography (GPC)>

Apparatus: ACQUITY APC system (manufactured by Waters)
Column: Guard column SHODEX GPC KF-601 (2 columns), KF-602 KF-602.5, KF-603
Flow rate: 1.23 ml/min.
Column temperature: 25° C.
Solvent used: THE (tetrahydrofuran)
Detector: RI (differential refractometer)

### <Maleimide Equivalent>

Potentiometric titration apparatus: Automatic titration apparatus COM-1600 (manufactured by HIRANUMA Co., Ltd.)

Apparatus conditions: Reference electrode RE-201 (manufactured by HIRANUMA Co., Ltd.), platinum indicator electrode PT-301 (manufactured by HIRANUMA Co., Ltd.) Titration method: 0.5 g of sample is weighed into a beaker and dissolved in 20 mL of an equal volume mixture of chloroform and isopropyl alcohol. Then, 4 mL of a toluene solution containing 60 g/L triethylamine was added, and the mixture was reacted at room temperature for 30 minutes while stirring. After the reaction was completed, 30 mL of an equal volume mixture of chloroform and isopropyl alcohol was added, and titration was performed using a potentiometric titrator to obtain the desired maleimide equivalent.

### Example 1

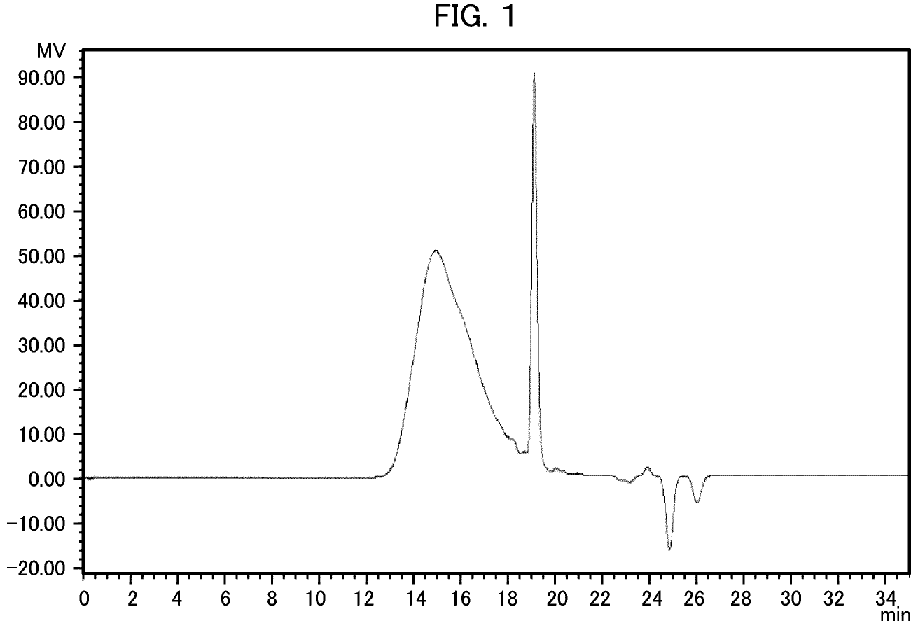

30.0 parts of toluene, 11.2 parts of n-methylpyrrolidone, 4.24 parts of 4,4′-methylenebis(2-ethyl-6-methylaniline), and 0.08 parts of methanesulfonic acid were charged into a flask equipped with a thermometer, a cooling tube, and a stirrer. After confirming that the solution became homogeneous, 22.0 parts of styrene-maleic anhydride copolymer (acid value: 50, Mn: 2,278, Mw: 3,903) were added over 5 hours at 120° C., and then the mixture was reacted at 120° C. for 16 hours. After cooling, 3.96 parts of maleic anhydride were added, and the reaction was continued for 8 hours at 130° C. under reflux. After cooling, the reaction solution was diluted with 200 parts of toluene, and the organic layer was washed five times with 100 parts of 80° C. warm water. The solvent was distilled off under reduced pressure with heating to obtain the target compound (M-1) as a brown solid resin (Mn: 1641, Mw: 3431, maleimide equivalent: 1180 g/eq.). The GPC chart of the obtained compound is shown in FIG. 1. The proportion of component (c) calculated from the peak area ratio was 14.6%. From the acid value and molecular weight of the raw material styrene-maleic anhydride copolymer, m was calculated to be 27.6 and n was calculated to be 1.3.

### Example 2

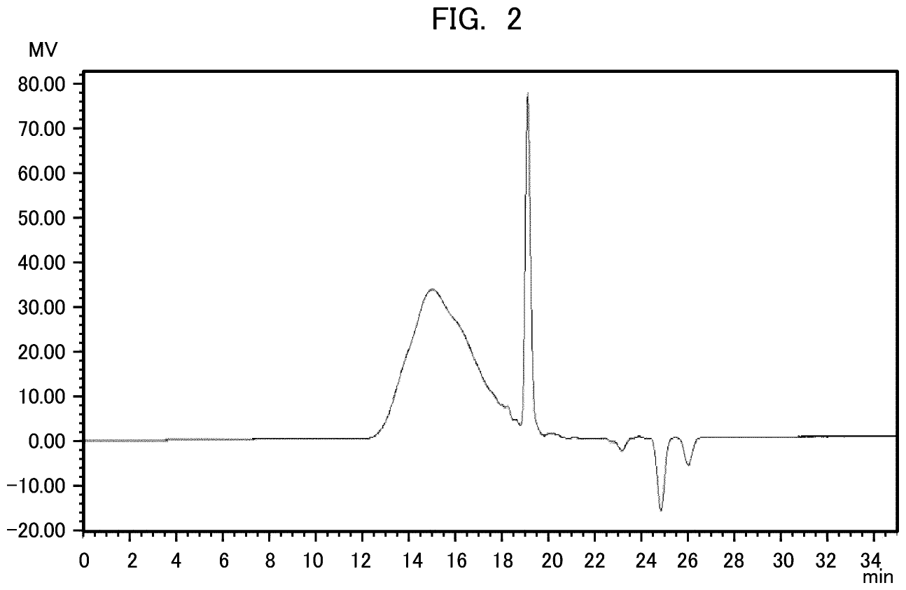

30.0 parts of toluene, 10 parts of n-methylpyrrolidone, 6.35 parts of 4,4′-methylenebis(2-ethyl-6-methylaniline), and 0.13 parts of methanesulfonic acid were charged into a flask equipped with a thermometer, a cooling tube, and a stirrer. After confirming that the solution was homogeneous, 19.8 parts of styrene-maleic anhydride copolymer (acid value: 85, Mn: 1,979, Mw: 3,088) were added over 5 hours at 120° C., and then the mixture was reacted at 120° C. for 10 hours. After cooling, 8.87 parts of maleic anhydride were added, and the reaction was continued for 6 hours at 130° C. under reflux. After cooling, the reaction solution was diluted with 300 parts of toluene, and the organic layer was washed five times with 100 parts of 10 wt % saline. The solvent was distilled off under heating and reduced pressure to obtain the target compound (M-2) as a brown solid resin (Mn: 1542, Mw: 3560). The GPC chart of the obtained compound is shown in FIG. 2. The ratio of component (c) calculated from the peak area ratio was 16.6%. From the acid value and molecular weight of the raw material styrene-maleic anhydride copolymer, m was calculated to be 26.7 and n was calculated to be 2.3.

### Example 3

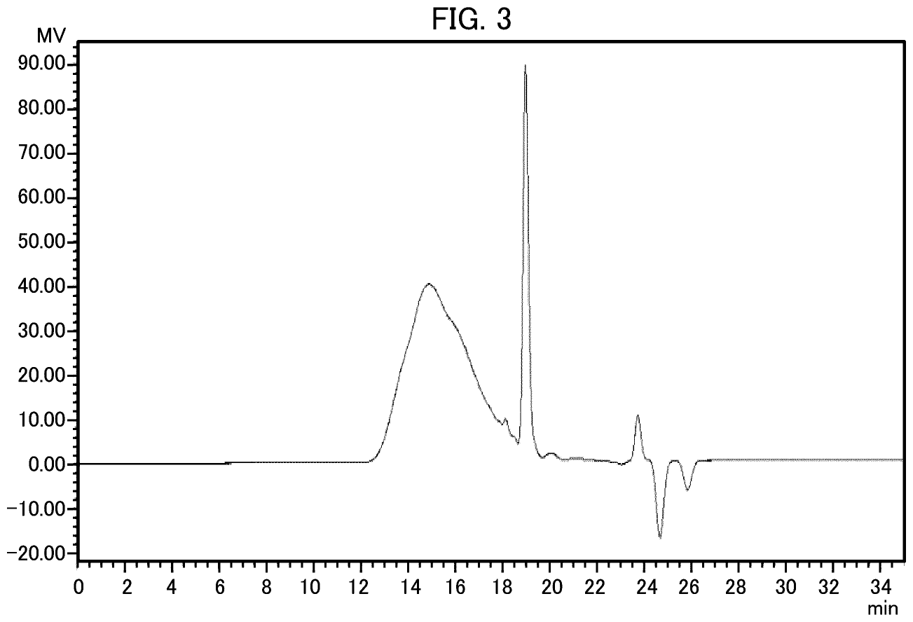

24.5 parts of toluene, 8.17 parts of n-methylpyrrolidone, 5.30 parts of 4,4′-methylenebis(2-ethyl-6-methylaniline), 0.21 parts of methanesulfonic acid, and 16.5 parts of styrene-maleic anhydride copolymer (acid value: 85, Mn: 1,979, Mw: 3,088) were charged into a flask equipped with a thermometer, a cooling tube, and a stirrer, and reacted at 120° C. for 15 hours. After cooling, 13.6 parts of toluene, 4.54 parts of n-methylpyrrolidone, and 3.06 parts of maleic anhydride were added, and the reaction was continued for 8 hours at 120° C. under reflux. After cooling, the reaction solution was diluted with 235 parts of toluene, and the organic layer was washed three times with 100 parts of 10 wt % saline and three times with 100 parts of 80° C. warm water. The solvent was distilled off under reduced pressure with heating to obtain the target compound (M-3) as a brown solid resin (Mn: 1555, Mw: 3625, maleimide equivalent: 920 g/eq.). The GPC chart of the obtained compound is shown in FIG. 3. The proportion of component (c) calculated from the peak area ratio was 16.4%. From the acid value and molecular weight of the raw material styrene-maleic anhydride copolymer, m was calculated to be 26.7 and n was calculated to be 2.3.

### Example 4

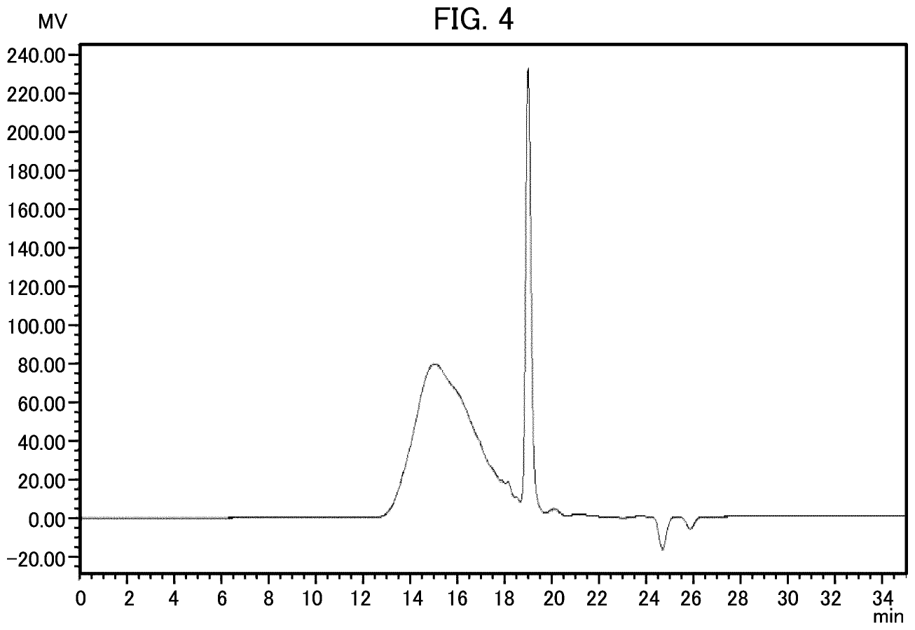

24.5 parts of toluene, 8.17 parts of n-methylpyrrolidone, 5.30 parts of 4,4′-methylenebis(2-ethyl-6-methylaniline), and 0.21 parts of methanesulfonic acid were charged into a flask equipped with a thermometer, a cooling tube, and a stirrer. After confirming that the solution was homogeneous, 16.5 parts of styrene-maleic anhydride copolymer (acid value: 85, Mn: 1,979, Mw: 3,088) were added over 5 hours at 120° C., and then the mixture was reacted for 10 hours at 120° C. After cooling, 13.6 parts of toluene, 4.54 parts of n-methylpyrrolidone, and 3.06 parts of maleic anhydride were added, and the reaction was continued for 8 hours at 122° C. under reflux. After cooling, the reaction solution was diluted with 235 parts of toluene, and the organic layer was washed three times with 100 parts of 10 wt % saline and three times with warm water at 80° C. The solvent was distilled off under reduced pressure with heating to obtain the target compound (M-4) as a brown solid resin (Mn: 1340, Mw: 2858, maleimide equivalent: 780 g/eq.). The GPC chart of the obtained compound is shown in FIG. 4. The proportion of component (c) calculated from the peak area ratio was 21.5%. From the acid value and molecular weight of the raw material styrene-maleic anhydride copolymer, m was calculated to be 26.7 and n was calculated to be 2.3.

### Example 5

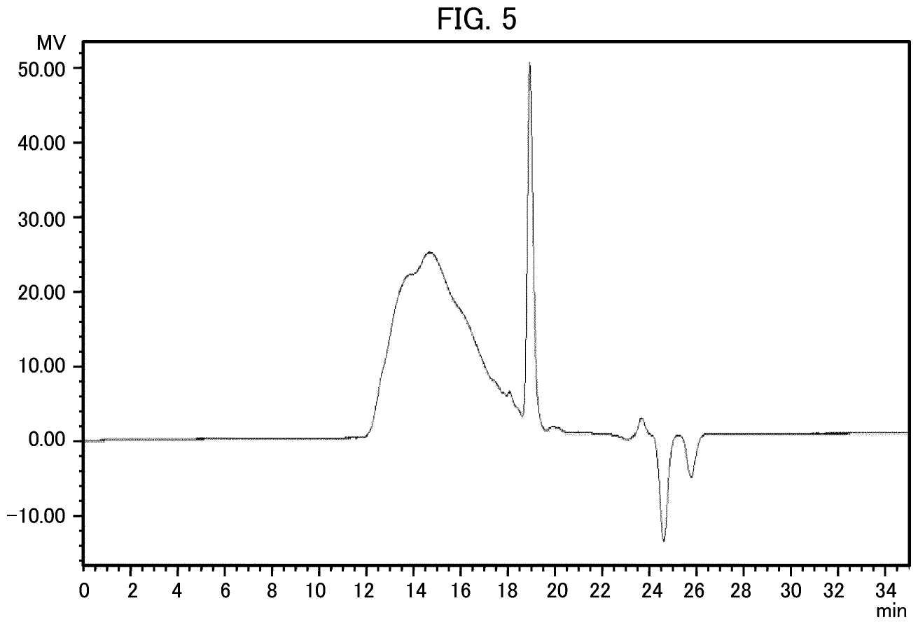

20.0 parts of toluene, 6.66 parts of n-methylpyrrolidone, 5.30 parts of 4,4′-methylenebis(2-ethyl-6-methylaniline), 0.21 parts of methanesulfonic acid, and 16.5 parts of styrene-maleic anhydride copolymer (acid value: 85, Mn: 1,979, Mw: 3,088) were charged into a flask equipped with a thermometer, a cooling tube, and a stirrer, and reacted at 120° C. for 32 hours. After cooling, 18.2 parts of toluene, 6.06 parts of n-methylpyrrolidone, and 3.06 parts of maleic anhydride were added, and the reaction was continued for 8 hours at 120° C. under reflux. After cooling, the reaction solution was diluted with 235 parts of toluene, and the organic layer was washed three times with 100 parts of 10 wt % saline and three times with 100 parts of 80° C. warm water. The solvent was distilled off under reduced pressure with heating to obtain the target compound (M-5) as a brown solid resin (Mn: 1812, Mw: 5985, maleimide equivalent: 940 g/eq.). The GPC chart of the obtained compound is shown in FIG. 5. The proportion of component (c) calculated from the peak area ratio was 12.6%. From the acid value and molecular weight of the raw material styrene-maleic anhydride copolymer, m was calculated to be 26.7 and n was calculated to be 2.3.

### Example 6

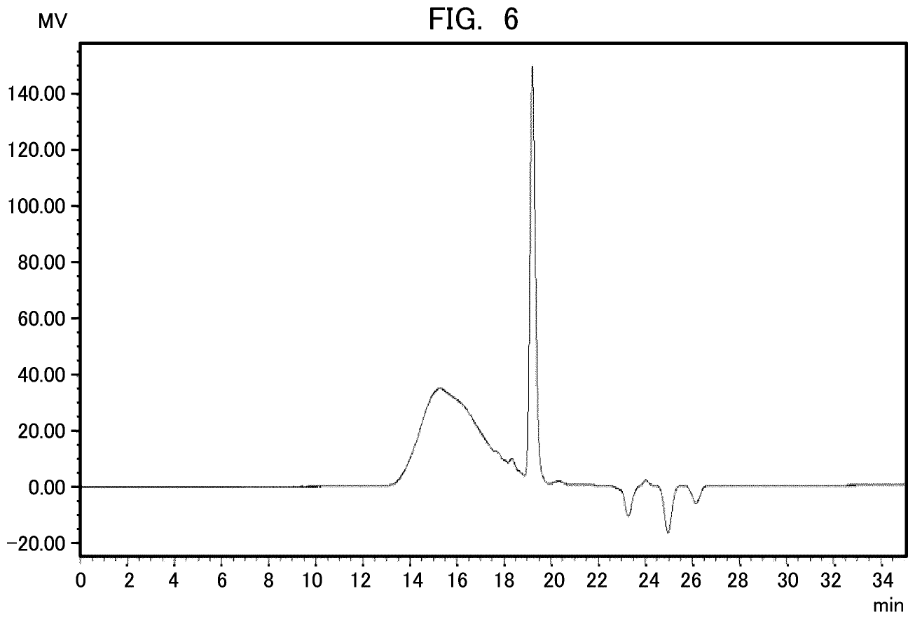

60.0 parts of toluene, 20 parts of n-methylpyrrolidone, 8.47 parts of 4,4′-methylenebis(2-ethyl-6-methylaniline), and 0.17 parts of methanesulfonic acid were charged into a flask equipped with a thermometer, a cooling tube, and a stirrer. After confirming that the solution was homogeneous, 20.0 parts of styrene-maleic anhydride copolymer (acid value: 140, Mn: 1,978, Mw: 3,107) were added over 5 hours at 120° C., and then the mixture was reacted at 120° C. for 10 hours. After cooling, 4.00 parts of maleic anhydride were added, and the reaction was continued for 13 hours at 120° C. under reflux. After cooling, the reaction solution was diluted with 100 parts of toluene, and the organic layer was washed five times with 100 parts of 80° C. warm water. The solvent was distilled off under reduced pressure with heating to obtain the target compound (M-6) as a brown solid resin (Mn: 1173, Mw: 2554, maleimide equivalent: 650 g/eq.). The GPC chart of the obtained compound is shown in FIG. 6. The proportion of component (c) calculated from the peak area ratio was 28.8%. From the acid value and molecular weight of the raw material styrene-maleic anhydride copolymer, m was calculated to be 25.3 and n was calculated to be 3.7.

### Example 7

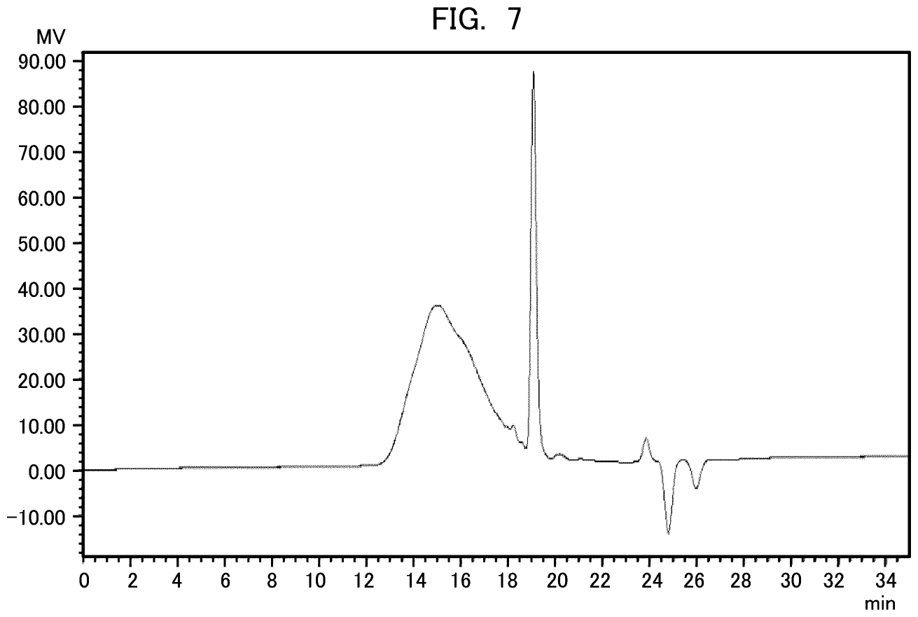

30.1 parts of toluene, 10.0 parts of n-methylpyrrolidone, 6.35 parts of 4,4′-methylenebis(2-ethyl-6-methylaniline), and 0.25 parts of methanesulfonic acid were charged into a flask equipped with a thermometer, a cooling tube, and a stirrer. After confirming that the solution was homogeneous, 19.8 parts of styrene-maleic anhydride copolymer (acid value: 85, Mn: 1,979, Mw: 3,088) were charged, and the mixture was added over 5 hours at 120° C., and then reacted for 10 hours at 120° C. After cooling, 15.0 parts of toluene, 5.0 parts of n-methylpyrrolidone, and 3.56 parts of maleic anhydride were added, and the reaction was continued for 8 hours at 120° C. under reflux. After cooling, the reaction solution was diluted with 285 parts of toluene, and the organic layer was washed six times with 100 parts of 10 wt % saline and three times with 100 parts of 80° C. warm water. The solvent was distilled off under heating and reduced pressure to obtain the target compound (M-7) as a brown solid resin (Mn: 1491, Mw: 3402). The GPC chart of the obtained compound is shown in FIG. 7. The proportion of component (c) calculated from the peak area ratio was 17.7%. From the acid value and molecular weight of the raw material styrene-maleic anhydride copolymer, m was calculated to be 26.7 and n was calculated to be 2.3.

### Comparative Example 1

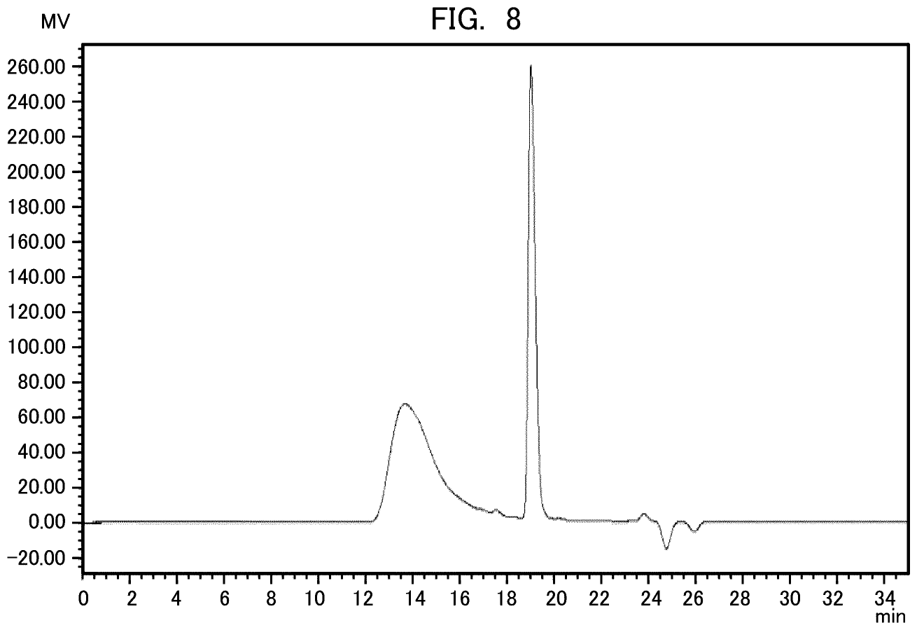

75.0 parts of toluene, 25.0 parts of n-methylpyrrolidone, 8.47 parts of 4,4′-methylenebis(2-ethyl-6-methylaniline), 0.17 parts of methanesulfonic acid, and 18.7 parts of styrene-maleic anhydride copolymer (acid value: 60, Mn: 6,686, Mw: 11,295) were charged into a flask equipped with a thermometer, a cooling tube, and a stirrer, and reacted at 120° C. for 2 hours. After cooling, 5.88 parts of maleic anhydride were added, and the reaction was continued for 6 hours at 120° C. under reflux. After cooling, the reaction solution was diluted with 50 parts of toluene, and the organic layer was washed five times with 100 parts of hot water at 80° C. The solvent was distilled off under heating and reduced pressure to obtain the target compound (M-8) as a brown solid resin. The GPC chart of the obtained compound is shown in FIG. 8. The proportion of component (c) calculated from the peak area ratio was 37.7%. From the acid value and molecular weight of the raw material styrene-maleic anhydride copolymer, m was calculated to be 92.4 and n was calculated to be 5.4.

### Comparative Example 2

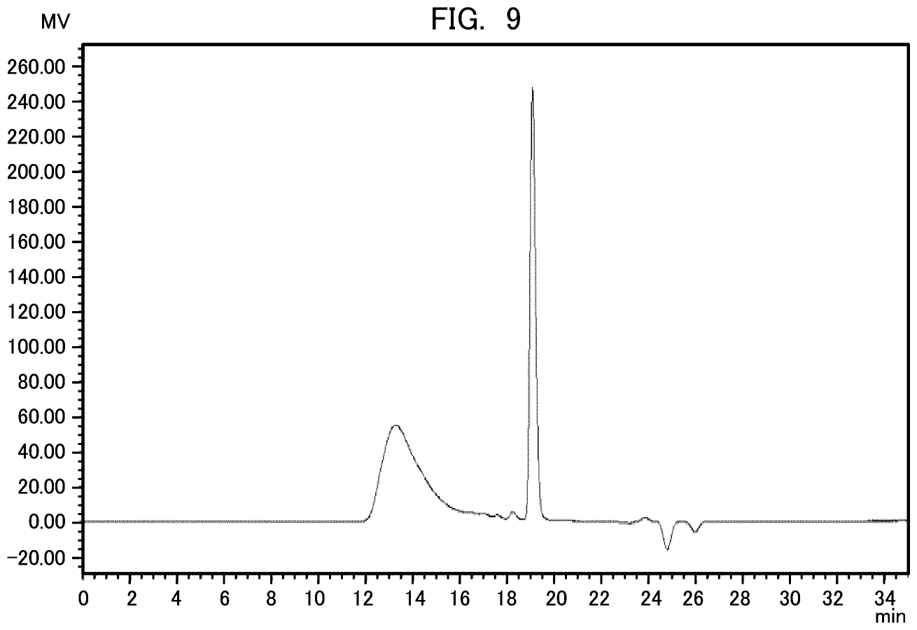

75.0 parts of toluene, 25.0 parts of n-methylpyrrolidone, 14.12 parts of 4,4′-methylenebis(2-ethyl-6-methylaniline), 0.28 parts of methanesulfonic acid, and 23.4 parts of styrene-maleic anhydride copolymer (acid value: 120, Mn: 5,984, Mw: 14,768) were charged into a flask equipped with a thermometer, a cooling tube, and a stirrer, and reacted at 120° C. for 3 hours. After cooling, 9.81 parts of maleic anhydride were added, and the reaction was continued for 8 hours at 120° C. under reflux. After cooling, the reaction solution was diluted with 100 parts of toluene, and the organic layer was washed five times with 100 parts of hot water at 80° C. The solvent was distilled off under heating and reduced pressure to obtain the target compound (M-9) as a brown solid resin (Mn: 1210, Mw: 8644). The GPC chart of the obtained compound is shown in FIG. 9. The ratio of component (c) calculated from the peak area ratio was 37.8%. From the acid value and molecular weight of the raw material styrene-maleic anhydride copolymer, m was calculated to be 116.2 and n was calculated to be 14.4.

### Comparative Example 3

75.0 parts of toluene, 25.0 parts of n-methylpyrrolidone, 5.65 parts of 4,4′-methylenebis(2-ethyl-6-methylaniline), 0.11 parts of methanesulfonic acid, and 18.7 parts of styrene-maleic anhydride copolymer (acid value: 60, Mn: 6,686, Mw: 11,295) were charged into a flask equipped with a thermometer, a cooling tube, and a stirrer, and reacted at 120° C. for 2 hours. After cooling, 2.94 parts of maleic anhydride were added, and the reaction was continued for 17 hours at 130° C. under reflux. After cooling, the reaction solution was diluted with 50 parts of toluene, and an attempt was made to wash the organic layer with 100 parts of 80° C. warm water, but the organic layer and the aqueous layer did not separate.

### <Solvent Solubility and Storage Stability Test>

Toluene was added to the maleimide resin mixtures obtained in Examples 1 to 7 and Comparative Examples 1 to 2, and the maleimide resin (Mn: 2126, Mw: 11527) described in Example 12 of Japanese Patent No. 7208705 so that the resin content was 60% by weight, and the mixtures were stirred. As a result, the maleimide resin mixtures obtained in Examples 1 to 7 and Comparative Examples 1 to 2 were dissolved in toluene, but the maleimide resin described in Example 12 of Japanese Patent No. 7208705 was not dissolved in toluene.

Next, 1 g of the toluene solutions of 60% by weight of the resin content of the maleimide resin mixtures obtained in Examples 1 to 7 and Comparative Examples 1 to 2 were dissolved were placed in a 6 cc screw tube bottles, sealed with lids, and left to stand in a refrigerator at 5.0 to 10.0° C. for 24 hours, after which the presence or absence of crystal precipitation was visually confirmed. The results are shown in Table 1, with “O” for no crystal precipitation and “X” for precipitation.

Since the maleimide resin described in Example 12 of Japanese Patent No. 7208705 did not dissolve in toluene under the above conditions, the amount of toluene was increased to confirm the solubility. It was confirmed that the maleimide resin did not dissolve in toluene when the resin content was 60 to 20% by weight, but dissolved in toluene when the resin content was 10% by weight. Thus, 1 g of a toluene solution of 10% by weight of the resin content of t the maleimide resin described in Example 12 of Japanese Patent No. 7208705 was placed in a 6 cc screw tube bottle, and the bottle was allowed to stand at room temperature for 24 hours with the lid closed and then visually checked for the presence or absence of crystal precipitation. As a result, it was confirmed that precipitation occurred.

TABLE 1

| | M-1 | M-2 | M-3 | M-4 | M-5 | M-6 | M-7 | M-8 | M-9 |
|---|---|---|---|---|---|---|---|---|---|
| Content of component (c) in | 14.6 | 16.6 | 16.4 | 21.5 | 12.6 | 28.8 | 17.7 | 37.7 | 37.8 |
| the total maleimide resin | | | | | | | | | |
| mixture | | | | | | | | | |
| (Area %) | | | | | | | | | |
| Storage Stability | ∘ | ∘ | ∘ | ∘ | ∘ | ∘ | ∘ | x | x |

From the results in Table 1, it was confirmed that the maleimide resin mixtures obtained in Examples 1 to 7 had excellent solvent solubility and storage stability in the solution state (varnish).

### Examples 8 to 11, Comparative Examples 4 to 6

A frame-shaped cushion paper with a thickness of 250 μm, cut out to 100 mm×50 mm in the center, was placed on the first copper foil, and 5.0 g of a sample mixed in the ratio of Table 2 was placed in the center of the frame. The cushion paper and the sample were sandwiched between the second copper foil facing the first copper foil and the first copper foil, and molded in a vacuum hot press and cured at 220° C. for 2 hours. Then, the first and second copper foils were etched using ferric chloride to obtain a cured film. The dielectric loss tangent of the cured film was measured by the method described below and is shown in Table 2.

### <Dielectric Loss Tangent Test>

A test was performed by a cavity resonator perturbation method at 25° C. using a 10 GHz cavity resonator manufactured by AET Co., Ltd. The test was performed on a sample with a width of 2.5 mm, a length of 100 mm, and a thickness of 0.20 mm.

TABLE 2

| | | | | | | |
|---|---|---|---|---|---|---|
| | | | | Comparative | Comparative | Comparative |
| Example 8 | Example 9 | Example 10 | Example 11 | Example 4 | Example 5 | Example 6 |

| | | | | | | | |
|---|---|---|---|---|---|---|---|
| Maleimide | M-2 | 100 | | | | | |
| Resin | M-3 | | 100 | | | | |
| Mixture | M-4 | | | 100 | | | |
| | M-7 | | | | 75 | | |
| | M-8 | | | | | 100 | |
| | M-9 | | | | | | 100 |

| | | | | | | | |
|---|---|---|---|---|---|---|---|
| OPE-2St-2200 | | | | 25 | | | 100 |
| 2E4MZ | 1 | 1 | 1 | | 1 | 1 | |

Evaluation Result

| | | | | | | | |
|---|---|---|---|---|---|---|---|
| Dielectric | 0.00111 | 0.00101 | 0.00124 | 0.00118 | 0.00189 | 0.0162 | 0.00165 |
| Loss Tangent | | | | | | | |

OPE-2St-2200: (polyphenylene ether compound having a styrene structure, manufactured by Mitsubishi Gas Chemical Co., Ltd.)
2E4MZ: 2-ethyl-4-methylimidazole (curing accelerator, manufactured by Shikoku Chemical Industries, Ltd.)

From the results in Table 2, it was confirmed that Examples 8 to 11 had excellent low dielectric tangents.

The attenuation rate of a signal flowing through the dielectric material constituting the printed wiring board is proportional to the dielectric tangent. Since the attenuation of a signal directly generates heat and causes a rise in temperature, a low dielectric tangent is important for printed wiring board materials and the like.

### Example 8, Comparative Example 6

The glass transition temperature (Tg) of Example 8 and Comparative Example 6, which were blended in the ratios shown in Table 2, was measured under the following conditions. The results are shown in Table 3.

### <Glass Transition Temperature (Tg)>

Differential scanning calorimeter (DSC): DSC6220 (manufactured by SII NanoTechnology Inc.)
Measurement temperature range: 30 to 350° C.
Heating rate: 10° C./min
Atmosphere: Nitrogen (30 mL/min)
Sample amount: 5 mg

TABLE 3

| | | Comparative |
|---|---|---|
| | Example 8 | Example 6 |
| Tg | 261.7° C. | 240.0° C. |

### [Maleimide Resin M-10]

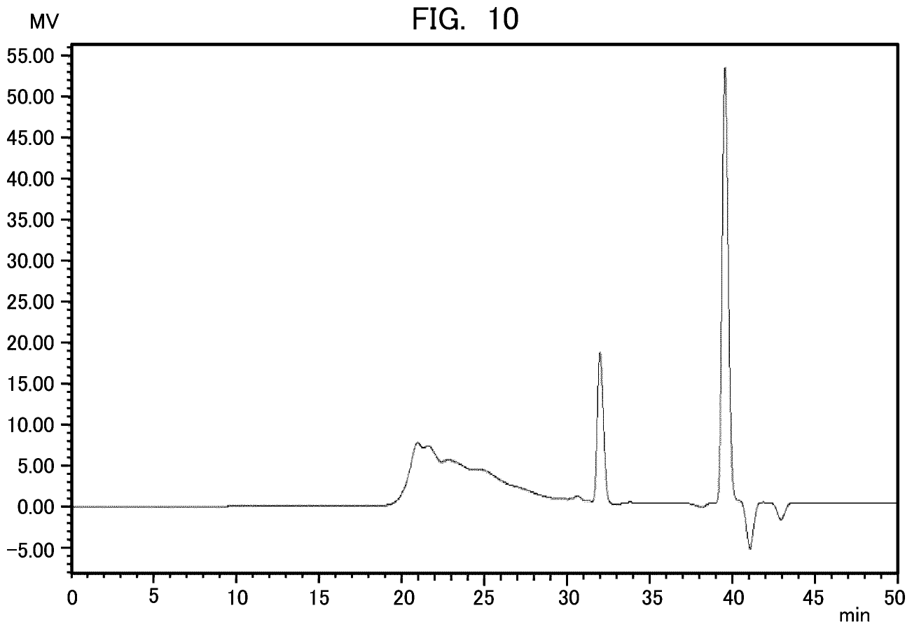

26.9 parts of toluene, 8.95 parts of n-methylpyrrolidone, 17.30 parts of 4,4′-methylenebis (2-ethyl-6-methylaniline), and 0.69 parts of methanesulfonic acid were charged into a flask equipped with a thermometer, a cooling tube, and a stirrer. After confirming that the solution was homogeneous, 36.4 parts of styrene-maleic anhydride copolymer (acid value: 150, Mn: 2,454, Mw: 4,997) were charged and reacted at 115±2° C. for 15 hours. After cooling, 13.4 parts of toluene, 9.0 parts of n-methylpyrrolidone, and 14.4 parts of maleic anhydride were added, and the reaction was continued for 6 hours at 120° C. under reflux. After cooling, the reaction solution was diluted with 645 parts of toluene, and the organic layer was washed four times with 245 parts of 10 wt % saline and three times with 245 parts of 80° C. warm water. The solvent was distilled off under heating and reduced pressure to obtain the target compound (M-10) as a toluene solution (Mn: 2281, Mw: 54801, maleimide equivalent: 810 g/eq.). The GPC chart of the obtained compound is shown in FIG. 10. The proportion of component (c) calculated from the peak area ratio was 17.2%. From the acid value and molecular weight of the raw material styrene-maleic anhydride copolymer, m was calculated to be 41.5 and n was calculated to be 6.7.

### Examples 12-14

A cushion paper with a thickness of 250 μm, cut out to 150 mm×150 mm in the center, was placed on the first copper foil, and 5.0 g of a sample mixed in the ratio of Table 4 was placed in the center of the frame. The cushion paper and the sample were sandwiched between the second copper foil facing the first copper foil and the first copper foil, and molded in a vacuum hot press and cured at 220° C. for 2 hours. Then, the first and second copper foils were etched using ferric chloride to obtain a cured film. The dielectric loss tangent and glass transition temperature (Tg) of the cured film were measured by the method described below and are shown in Table 4.

### <Dielectric Tangent Test>

Using a 10 GHz cavity resonator manufactured by AET Co., Ltd., the test was performed at 25° C. using the cavity resonator perturbation method. The sample size was 2.5 mm wide×100 mm long, and the thickness was 0.20 mm.

### <Glass Transition Temperature (Tg)>

Dynamic viscoelasticity measuring device: DMA Q800 (TA instruments)
Measurement temperature range: 30 to 350° C.
Heating rate: 2° C./min
Sample size: 5 mm wide×40 mm long×0.5 mm thick
Criterion: The peak point of tan δ is regarded as Tg.

TABLE 4

| | | Example | Example | Example |
|---|---|---|---|---|
| | | 12 | 13 | 14 |
| Maleimide | M-7 | 1 | 7 | |
| Resin | M-10 | | | 5 |
| Polyphenylene | SA-9000-111 | | | 5 |
| Ether Compound | OPE-2st 2200 | 1 | | |
| Compound Containing | S-1 | | 3 | |
| Ethylenically Unsaturated Bond | TAIC | | | 1.6 |
| [symbol] ene Butadiene Copolymer | Ricon100 | | | 2 |
| [symbol] ermoplastic Elastomer | Septon 2104 | | | 3 |
| Curing Accelerator | DCP | | | 0.17 |
| Evaluation Result | Dielectric Loss Tangent | 0.00151 | 0.00143 | 0.0012 |
| | Tg [° C.] | 194.8 | 152.3 | 200 |

[symbol]

indicates data missing or illegible when filed

SA-9000-111 (polyphenylene ether compound having a methacrylate structure, manufactured by Sabic Corporation)
OPE-2St-2200 (polyphenylene ether compound having a styrene structure, manufactured by Mitsubishi Gas Chemical Company, Inc.)
S-1 (a styrene resin obtained by the method described in Example 1 of Japanese Patent No. 7353538, in which the solvent was distilled off by heating under reduced pressure) TAIC (triallyl isocyanurate, manufactured by Mitsubishi Chemical Corporation) Septon 2104 (styrene-ethylene-propylene-styrene-rubber, manufactured by Kuraray Co., Ltd.)
DCP (dicumyl peroxide, manufactured by Nouryon Chemical Co., Ltd.)

From the results in Table 4, it was confirmed that the dielectric tangents of Examples 12 to 14 were less than 0.0016 and had excellent dielectric properties.

The attenuation rate of a signal flowing through the dielectric constituting the printed wiring board is proportional to the dielectric tangent. Since the attenuation of a signal directly generates heat and causes a temperature rise, a low dielectric tangent is important for printed wiring board materials and the like.

This application claims priority based on Japanese Patent Application No. 2023-046176 filed on Mar. 23, 2023 and Japanese Patent Application No. 2023-217507 filed on Dec. 25, 2023.

### INDUSTRIAL APPLICABILITY

The curable resin composition of the present invention and its cured product are useful for applications such as insulating materials for electric and electronic components (highly reliable semiconductor encapsulating materials, etc.), laminates (printed wiring boards, BGA substrates, build-up substrates, etc.), adhesives (conductive adhesives, etc.), various composite materials such as CFRP, paints, and 3D printing.

1. A maleimide resin mixture comprising:
a maleimide resin having repeating units of the following formulas (a) and (b); and
a maleimide resin represented by the following formula (c), wherein
the content of the maleimide resin represented by the formula (c) in the total amount of the maleimide resin mixture is 5.0 to 30.0 area % in terms of GPC area percentage: 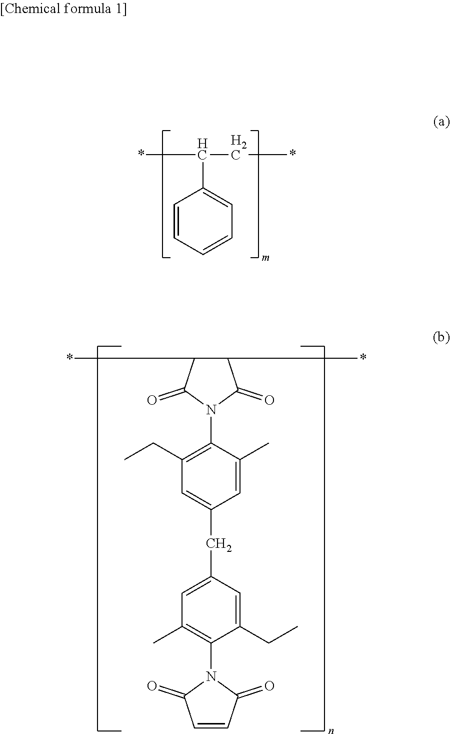
in the above formulas,
m is an average number of repeats, and 0<m<200,
n is an average number of repeats, and 0<n<100,
(a) and (b) are each bonded with *, and the repeat positions may be random;

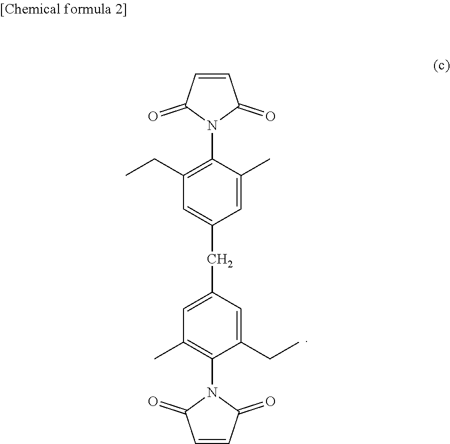 [SMILES: CCc1cc(Cc2cc(C)c(N3C(=O)C=CC3=O)c(CC)c2)cc(C)c1N1C(=O)C=CC1=O]

2. (canceled)

3. (canceled)

4. A curable resin composition comprising the maleimide resin mixture according to claim 1.

5. The curable resin composition according to claim 4, further comprising at least one selected from the group consisting of a maleimide resin other than the maleimide resin mixture, a polyphenylene ether compound, a compound having an ethylenically unsaturated bond, a cyanate ester resin, polybutadiene and modified products thereof, polystyrene and modified products thereof, and polyethylene and modified products thereof.

6. The curable resin composition according to claim 4, further comprising a curing accelerator.

7. The curable resin composition according to claim 4, which is for a printed wiring board.

8. A varnish comprising the maleimide resin mixture according to claim 1 and an organic solvent.

9. A varnish comprising the curable resin composition according to claim 4 and an organic solvent.

10. A cured product obtained by curing the maleimide resin mixture according to claim 1.

11. A cured product obtained by curing the curable resin composition according to claim 4.

12. The cured product according to claim 11, having a dielectric tangent at a frequency of 10 GHz measured at 25° C. of less than 0.0016.
